(19) United States
(12) Patent Application Publication
(10) Pub. No.: US 2021/0013238 A1
(43) Pub. Date: Jan. 14, 2021

(54) ACTIVE MATRIX SUBSTRATE AND METHOD FOR MANUFACTURING SAME

(71) Applicant: Sharp Kabushiki Kaisha, Sakai City (JP)

(72) Inventors: Masahiko SUZUKI, Sakai City (JP); Yoshihito HARA, Sakai City (JP); Tetsuo KIKUCHI, Sakai City (JP); Setsuji NISHIMIYA, Sakai City (JP); Kengo HARA, Sakai City (JP); Masamitsu YAMANAKA, Sakai City (JP); Hitoshi TAKAHATA, Sakai City (JP); Hajime IMAI, Sakai City (JP); Tohru DAITOH, Sakai City (JP)

(21) Appl. No.: 16/919,422

(22) Filed: Jul. 2, 2020

Related U.S. Application Data
(60) Provisional application No. 62/871,760, filed on Jul. 9, 2019.

(51) Int. Cl. H01L 27/12; G02F 1/1362; G02F 1/1368

(52) U.S. Cl. CPC H01L 27/1225; G02F 1/136286; G02F 1/134363; G02F 1/136227; H01L 27/127; G02F 1/1368

(57) ABSTRACT

An active matrix substrate includes a substrate; a plurality of gate bus lines and a plurality of source bus lines; an oxide semiconductor TFT that includes an oxide semiconductor layer, a gate insulating layer, and a gate electrode; a pixel electrode; and an upper insulating layer. The oxide semiconductor layer includes a high resistance region, and a first region and a second region. The high resistance region includes a channel region, a first channel offset region, and a second channel offset region. The upper insulating layer is disposed so as to overlap the channel region, the first channel offset region, and the second channel offset region, and so as not to overlap any of the first region and the second region, when viewed from the normal direction of the main surface of the substrate.

### CROSS-REFERENCE TO RELATED APPLICATION

The present application claims priority from Provisional Application No. 62/871,760, the content of which is hereby incorporated by reference into this application.

### BACKGROUND OF THE INVENTION

### 1. Field of the Invention

The present invention relates to an active matrix substrate and a method for manufacturing the same.

### 2. Description of the Related Art

An active matrix substrate used for a display device includes a display region having a plurality of pixel regions and a non-display region other than the display region (also referred to as a “frame region” or a “peripheral region”). The pixel region is a region corresponding to a pixel of the display device. In each pixel region, a thin film transistor (hereinafter, “TFT”) is disposed as a switching element. The TFT disposed in each pixel region is called “pixel TFT”.

In recent years, it has been proposed to use an oxide semiconductor instead of amorphous silicon or polycrystalline silicon as a material for an active layer of the TFT. Such a TFT is referred to as an “oxide semiconductor TFT”. The oxide semiconductor has higher mobility than amorphous silicon. Therefore, the oxide semiconductor TFT can operate at higher speed than an amorphous silicon TFT. Since an oxide semiconductor film is formed by a simpler process than a polycrystalline silicon film, the oxide semiconductor film can be applied to an apparatus which requires a large area.

Most oxide semiconductor TFTs are bottom gate type TFTs, and a top gate type oxide semiconductor TFT has also been proposed. For example, Japanese Unexamined Patent Application Publication No. 2015-109315 and International Publication No. 2015/186619 disclose a top gate TFT in which a gate electrode is provided on a portion of an oxide semiconductor layer via a gate insulating layer.

### SUMMARY OF THE INVENTION

As a result of a study by the present inventors, in the oxide semiconductor TFT in the related art, having a top gate structure, an effective channel length might be shortened. When the effective channel length is short, depletion may occur, and desired TFT characteristics may not be obtained. Details will be described later.

An embodiment of the present invention provides an active matrix substrate provided with an oxide semiconductor TFT that may have stable characteristics.

The present specification discloses an active matrix substrate and a method for manufacturing the active matrix substrate described in the following items.

[Item 1]

An embodiment of the present invention provides an active matrix substrate that includes a display region having a plurality of pixel regions, the active matrix substrate including a substrate, a plurality of gate bus lines and a plurality of source bus lines that are supported on a main surface of the substrate, an oxide semiconductor TFT that is disposed in association with each of the plurality of pixel regions, and that includes an oxide semiconductor layer, a gate insulating layer disposed on a portion of the oxide semiconductor layer, and a gate electrode disposed on a portion of the gate insulating layer and electrically connected to one of the plurality of gate bus lines, a pixel electrode that is disposed in each of the plurality of pixel regions, and an upper insulating layer that is formed of a photosensitive SOG film or a photosensitive resin film, and that is disposed on the gate electrode and the gate insulating layer so as to cover an upper surface and a side surface of the gate electrode, in which the oxide semiconductor layer includes a high resistance region, and a first region and a second region that are respectively located on both sides of the high resistance region and have a lower resistivity than that of the high resistance region, the first region is electrically connected to one of the plurality of source bus lines, and the second region is electrically connected to the pixel electrode, the high resistance region includes a channel region that overlaps the gate electrode when viewed from a normal direction of the main surface of the substrate, a first channel offset region located between the first region and the channel region, and a second channel offset region located between the second region and the channel region, and the upper insulating layer is disposed so as to overlap the channel region, the first channel offset region, and the second channel offset region, and so as not to overlap any of the first region and the second region, when viewed from the normal direction of the main surface of the substrate.

[Item 2]

In the active matrix substrate according to Item 1, the upper insulating layer is in direct contact with the upper surface and the side surface of the gate electrode and a portion of an upper surface of the gate insulating layer which is located around the gate electrode, and is not in direct contact with the oxide semiconductor layer, and a peripheral edge of the upper insulating layer and a peripheral edge of the upper surface of the gate insulating layer are coincided with each other when viewed from the normal direction of the main surface of the substrate.

[Item 3]

In the active matrix substrate according to Item 1 or 2, the gate electrode is formed using the same conductive film as that of the plurality of gate bus lines, each of the plurality of gate bus lines is located on a portion of the gate insulating layer, and an upper surface and a side surface of each of the plurality of gate bus lines are covered with the upper insulating layer.

[Item 4]

The active matrix substrate according to any one of Items 1 to 3, further including a first interlayer insulating layer that covers the oxide semiconductor TFT and the upper insulating layer, in which the oxide semiconductor TFT further includes a source electrode formed of the same conductive film as that of the plurality of source bus lines, and the source electrode is disposed on the first interlayer insulating layer and in a source opening portion formed in the first interlayer insulating layer, and is connected to the first region of the oxide semiconductor layer in the source opening portion.

[Item 5]

In the active matrix substrate according to Item 4, the oxide semiconductor TFT further includes a lower electrode or a light shielding layer that is disposed on the substrate side of the channel region of the oxide semiconductor layer via a lower insulating layer.

[Item 6]

The active matrix substrate according to Item 5, further including a lower electrode connecting portion that electrically connects the lower electrode to the one of the plurality of source bus lines, in which the lower electrode connecting portion includes a lower conductive layer that is electrically connected to the lower electrode, the lower insulating layer and the first interlayer insulating layer that are extended on the lower conductive layer, and an upper conductive layer that is electrically connected to the one of the plurality of source bus lines, and the upper conductive layer is disposed on the first interlayer insulating layer and in a contact hole formed in the first interlayer insulating layer and the lower insulating layer, and is connected to the lower conductive layer in the contact hole.

[Item 7]

In the active matrix substrate according to Item 6, the contact hole includes an opening portion of the lower insulating layer and an opening portion of the first interlayer insulating layer, and a side surface of the opening portion of the lower insulating layer and a side surface of the opening portion of the first interlayer insulating layer are coincided with each other.

[Item 8]

In the active matrix substrate according to Item 6 or 7, the lower insulating layer includes a thin film portion disposed so as to overlap at least a portion of the lower conductive layer when viewed from the normal direction of the main surface of the substrate, and having a smaller thickness than that of the other portion of the lower conductive layer, and at least a portion of the opening portion of the lower insulating layer is formed in the thin film portion.

[Item 9]

The active matrix substrate according to Item 5, further including a lower electrode connecting portion that electrically connects the lower electrode to the one of the plurality of gate bus lines, in which the lower electrode connecting portion includes a lower conductive layer that is electrically connected to the lower electrode, the lower insulating layer that is extended on the lower conductive layer, a gate insulating layer that is disposed on a portion of the lower conductive layer via the lower insulating layer, a gate connecting layer that is electrically connected to the one of the plurality of gate bus lines, and that is disposed on a portion of the gate insulating layer, the upper insulating layer and the first interlayer insulating layer that are extended on the gate connecting layer, and a source connecting layer that is formed using the same conductive film as that of the plurality of source bus lines, and that is electrically insulated from the plurality of source bus lines, the source connecting layer is disposed on the first interlayer insulating layer and in a contact hole formed in the first interlayer insulating layer, the upper insulating layer, the gate insulating layer, and the lower insulating layer, and is connected to the lower conductive layer and the gate connecting layer in the contact hole, and a side surface of an opening portion of the upper insulating layer is coincided with a side surface of an opening portion of the first interlayer insulating layer in the contact hole.

[Item 10]

In the active matrix substrate according to any one of Items 1 to 3, the oxide semiconductor TFT further includes a source electrode formed of the same conductive film as that of the plurality of source bus lines, the active matrix substrate further comprises a lower insulating layer that covers the source electrode and the plurality of source bus lines, the oxide semiconductor layer is disposed on the lower insulating layer, and the first region of the oxide semiconductor layer is disposed on the lower insulating layer and in a source opening portion formed in the lower insulating layer, and is connected to the source electrode in the source opening portion.

[Item 11]

The active matrix substrate according to Item 10, further including an insulating layer that covers the oxide semiconductor layer, the gate electrode, and the upper insulating layer, in which the pixel electrode is disposed on the insulating layer and is in direct contact with the second region of the oxide semiconductor layer in a pixel contact hole formed in the insulating layer.

[Item 12]

The active matrix substrate according to Item 10, further including a first interlayer insulating layer that covers the oxide semiconductor TFT and the upper insulating layer, in which the oxide semiconductor TFT further includes a drain electrode, and the drain electrode is disposed on the first interlayer insulating layer and in a drain opening portion formed in the first interlayer insulating layer, and is connected to the second region of the oxide semiconductor layer in the drain opening portion, and the pixel electrode is electrically connected to the second region via the drain electrode.

[Item 13]

In the active matrix substrate according to any one of Items 10 to 12, the oxide semiconductor TFT further includes a lower electrode or a light shielding layer that is disposed on the substrate side of the channel region of the oxide semiconductor layer via the lower insulating layer, and the lower electrode or the light shielding layer is formed using the same conductive film as that of the plurality of source bus lines.

[Item 14]

In the active matrix substrate according to any one of Items 1 to 13, the upper insulating layer is formed of the photosensitive SOG film.

[Item 15]

In the active matrix substrate according to any one of Items 1 to 14, the oxide semiconductor layer includes an In—Ga—Zn—O-based semiconductor.

[Item 16]

In the active matrix substrate according to Item 15, the In—Ga—Zn—O-based semiconductor includes a crystalline portion.

[Item 17]

An embodiment of the present invention provides a method for manufacturing an active matrix substrate that includes a display region having a plurality of pixel regions, and an oxide semiconductor TFT and a pixel electrode associated with each pixel region, the method including a step (A) of forming the oxide semiconductor layer of each of the oxide semiconductor TFTs, by forming an oxide semiconductor film on a main surface of a substrate and patterning the oxide semiconductor film, a step (B) of forming a gate insulating film that covers the oxide semiconductor layer, a step (C) of forming a resist layer from a resist film, by forming a gate conductive film and the resist film in this order on the gate insulating film, and exposing and developing the resist film using a photomask, a step (D) of forming a gate electrode of each of the oxide semiconductor TFTs by performing etching of the gate conductive film using the resist layer as a mask, and subsequently, removing the resist layer, in which the etching is performed under a condition that a width of the gate electrode is smaller than a width of the resist layer, and a region of the oxide semiconductor layer which overlaps the gate electrode is a channel region, when viewed from a normal direction of the main surface of the substrate, a step (E) of forming a photosensitive SOG film or a photosensitive resin film so as to cover the gate electrode and the gate insulating film, a step (F) of forming an upper insulating layer that covers an upper surface and a side surface of the gate electrode, by exposing, developing, and baking the photosensitive SOG film or the photosensitive resin film by using again the photomask used when forming the resist layer, a step (G) of patterning the gate insulating film using the upper insulating layer as a mask, and forming a gate insulating layer that covers a portion of the oxide semiconductor layer, in which when viewed from the normal direction of the main surface of the substrate, the gate insulating layer overlaps the channel region of the oxide semiconductor layer and regions located on both sides of the channel region, the regions located on both sides of the channel region are respectively first and second channel offset regions, and a first region of the oxide semiconductor layer located on a side of the first channel offset region opposite to the channel region and a second region located on a side of the second channel offset region opposite to the channel region are exposed from the upper insulating layer and the gate insulating layer, and a step (H) of performing a resistance lowering treatment of the oxide semiconductor layer to cause a resistivity of the first region and the second region to be smaller than a resistivity of the channel region, the first channel offset region, and the second channel offset region, in which the first region is a region electrically connected to a source electrode of the oxide semiconductor TFT, and the second region is a region electrically connected to the pixel electrode.

[Item 18]

In the method for manufacturing according to Item 17, the exposing is performed under a condition that a width of the upper insulating layer is larger than a width of the photomask, in the step (F).

[Item 19]

In the method for manufacturing according to Item 17 or 18, further including before the step (A), a step (a) of forming a lower electrode of each of the oxide semiconductor TFTs and a lower conductive layer electrically connected to the lower electrode, by forming a lower conductive film on the substrate and patterning the lower conductive film, and a step (b) of forming a lower insulating layer that covers the lower conductive layer and the lower electrode, in which in the step (A), the oxide semiconductor layer is formed on the lower insulating layer, and the method further comprises after the step (H), a step (c) of forming an interlayer insulating layer that covers each of the oxide semiconductor TFTs and the upper insulating layer, a step (d) of forming a contact hole that exposes a portion of the lower insulating layer by collectively etching the interlayer insulating layer and the lower insulating layer, and a step (e) of forming an upper conductive layer connected to the lower conductive layer in the contact hole, by forming an upper conductive film on the interlayer insulating layer and in the contact hole, and patterning the upper conductive film.

[Item 20]

In the method for manufacturing according to Item 19, the step (b) includes a step of thinning a portion of a region of the lower insulating layer which overlaps the lower conductive layer to form a thin film portion, and the contact hole is formed in the thin film portion of the lower insulating layer in the step (d).

[Item 21]

In the method for manufacturing according to Item 19 or 20, patterning of the oxide semiconductor film is performed using a PAN-based etching solution containing phosphoric acid, nitric acid, and acetic acid.

[Item 22]

In the method for manufacturing according to any one of Items 17 to 21, the oxide semiconductor film includes an In—Ga—Zn—O-based semiconductor.

[Item 23]

In the method for manufacturing according to Item 22, the In—Ga—Zn—O-based semiconductor includes a crystalline portion.

According to an embodiment of the present invention, there is provided the active matrix substrate provided with the oxide semiconductor TFT that can have stable characteristics.

### BRIEF DESCRIPTION OF DRAWINGS

FIG. 1 is a schematic diagram illustrating an example of a planar structure of an active matrix substrate 101.

FIG. 2A is a plan view illustrating a pixel region in the active matrix substrate 101 according to a first embodiment.

FIG. 2B is a cross-sectional view illustrating the pixel region in the active matrix substrate 101.

FIG. 3A is a step sectional view illustrating a method for forming a gate metal layer and an upper insulating layer.

FIG. 3B is a step sectional view illustrating the method for forming the gate metal layer and the upper insulating layer.

FIG. 3C is a step sectional view illustrating the method for forming the gate metal layer and the upper insulating layer.

FIG. 3D is a step sectional view illustrating the method for forming the gate metal layer and the upper insulating layer.

FIG. 3E is a step sectional view illustrating the method for forming the gate metal layer and the upper insulating layer.

FIG. 4A is a step sectional view illustrating another method for forming the gate metal layer and the upper insulating layer.

FIG. 4B is a step sectional view illustrating another method for forming the gate metal layer and the upper insulating layer.

FIG. 4C is a step sectional view illustrating another method for forming the gate metal layer and the upper insulating layer.

FIG. 5 is a plan view illustrating a lower electrode connecting portion 201 in the active matrix substrate 101.

FIG. 6A is a step sectional view illustrating an example of a method for manufacturing the active matrix substrate according 101.

FIG. 6B is a step sectional view illustrating an example of the method for manufacturing the active matrix substrate according 101.

FIG. 6C is a step sectional view illustrating an example of the method for manufacturing the active matrix substrate according 101.

FIG. 6D is a step sectional view illustrating an example of the method for manufacturing the active matrix substrate according 101.

FIG. 6E is a step sectional view illustrating an example of the method for manufacturing the active matrix substrate according 101.

FIG. 6F is a step sectional view illustrating an example of the method for manufacturing the active matrix substrate according 101.

FIG. 6G is a step sectional view illustrating an example of the method for manufacturing the active matrix substrate according 101.

FIG. 6H is a step sectional view illustrating an example of the method for manufacturing the active matrix substrate according 101.

FIG. 6I is a step sectional view illustrating an example of the method for manufacturing the active matrix substrate according 101.

FIG. 6J is a step sectional view illustrating an example of the method for manufacturing the active matrix substrate according 101.

FIG. 6K is a step sectional view illustrating an example of the method for manufacturing the active matrix substrate according 101.

FIG. 6L is a step sectional view illustrating an example of the method for manufacturing the active matrix substrate according 101.

FIG. 6M is a step sectional view illustrating an example of the method for manufacturing the active matrix substrate according 101.

FIG. 7 is a cross-sectional view illustrating another lower electrode connecting portion 202.

FIG. 8 is a cross-sectional view illustrating a terminal portion 301.

FIG. 9A is a step sectional view illustrating another method for manufacturing the active matrix substrate 101.

FIG. 9B is a step sectional view illustrating another method for manufacturing the active matrix substrate 101.

FIG. 9C is a step sectional view illustrating another method for manufacturing the active matrix substrate 101.

FIG. 9D is a step sectional view illustrating another method for manufacturing the active matrix substrate 101.

FIG. 9E is a step sectional view illustrating another method for manufacturing the active matrix substrate 101.

FIG. 9F is a step sectional view illustrating another method for manufacturing the active matrix substrate 101.

FIG. 9G is a step sectional view illustrating another method for manufacturing the active matrix substrate 101.

FIG. 9H is a step sectional view illustrating another method for manufacturing the active matrix substrate 101.

FIG. 9I is a step sectional view illustrating another method for manufacturing the active matrix substrate 101.

FIG. 10A is a step sectional view illustrating another method for manufacturing the active matrix substrate 101.

FIG. 10B is a step sectional view illustrating another method for manufacturing the active matrix substrate 101.

FIG. 10C is a step sectional view illustrating another method for manufacturing the active matrix substrate 101.

FIG. 10D is a step sectional view illustrating another method for manufacturing the active matrix substrate 101.

FIG. 10E is a step sectional view illustrating another method for manufacturing the active matrix substrate 101.

FIG. 10F is a step sectional view illustrating another method for manufacturing the active matrix substrate 101.

FIG. 10G is a step sectional view illustrating another method for manufacturing the active matrix substrate 101.

FIG. 10H is a step sectional view illustrating another method for manufacturing the active matrix substrate 101.

FIG. 10I is a step sectional view illustrating another method for manufacturing the active matrix substrate 101.

FIG. 11 is a cross-sectional view illustrating a pixel region of an active matrix substrate 102 according to a second embodiment.

FIG. 12A is a step sectional view illustrating a method for manufacturing the active matrix substrate 102.

FIG. 12B is a step sectional view illustrating the method for manufacturing the active matrix substrate 102.

FIG. 12C is a step sectional view illustrating the method for manufacturing the active matrix substrate 102.

FIG. 12D is a step sectional view illustrating the method for manufacturing the active matrix substrate 102.

FIG. 12E is a step sectional view illustrating the method for manufacturing the active matrix substrate 102.

FIG. 12F is a step sectional view illustrating the method for manufacturing the active matrix substrate 102.

FIG. 12G is a step sectional view illustrating the method for manufacturing the active matrix substrate 102.

FIG. 12H is a step sectional view illustrating the method for manufacturing the active matrix substrate 102.

FIG. 12I is a step sectional view illustrating the method for manufacturing the active matrix substrate 102.

FIG. 13 is a cross-sectional view illustrating a pixel region of an active matrix substrate 103 according to Modification Example 1.

FIG. 14 is a cross-sectional view illustrating a pixel region of an active matrix substrate 104 according to Modification Example 2.

FIG. 15A is a cross-sectional view of an oxide semiconductor TFT of Reference Example 1 having a top gate structure.

FIG. 15B is a cross-sectional view of an oxide semiconductor TFT of Reference Example 2 having a top gate structure.

### DETAILED DESCRIPTION OF THE INVENTION

Hereinafter, findings found as a result of the study by the present inventors will be described with reference to the drawings.

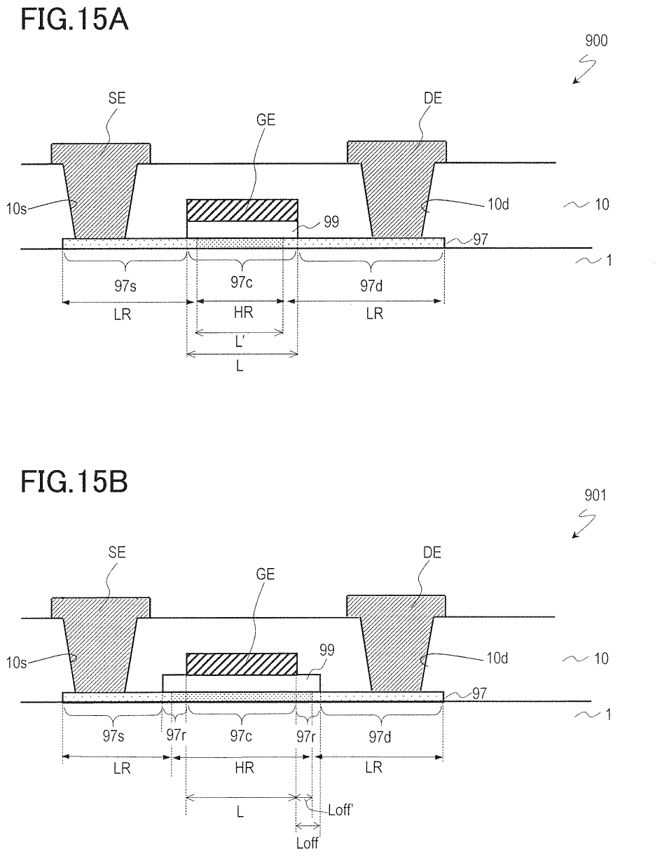

FIG. 15A is a cross-sectional view of an oxide semiconductor TFT 900 of Reference Example 1 having a top gate structure.

The TFT 900 of Reference Example 1 includes an oxide semiconductor layer 97 supported by a substrate 1, a gate electrode GE disposed on a portion of the oxide semiconductor layer 97 via a gate insulating layer 99, a first interlayer insulating layer 10 covering the gate electrode GE, and a source electrode SE and a drain electrode DE disposed on the first interlayer insulating layer 10.

The oxide semiconductor layer 97 includes a channel region 97c that overlaps the gate electrode GE and a first region 97s and a second region 97d that are located on both sides of the channel region 97c when viewed from a normal direction of a main surface of the substrate 1. The source electrode SE is in contact with the first region 97s of the oxide semiconductor layer 97 in a source opening portion 10s provided in the first interlayer insulating layer 10. The drain electrode DE is in contact with the second region 97d of the oxide semiconductor layer 97 in a drain opening portion 10d provided in the first interlayer insulating layer 10. The gate insulating layer 99 and the gate electrode GE may be patterned using the same photomask, for example.

In the TFT 900 having the top gate structure as described above, a resistance lowering treatment is performed so that a resistivity of the first region 97s and the second region 97d is lower than that of the channel region 97c. As a resistance lowering treatment, plasma treatment is performed on the oxide semiconductor layer 97 with the gate electrode GE and the gate insulating layer 99 as a mask, for example.

In the resistance lowering treatment, the resistance may be lowered to a portion of the oxide semiconductor layer 97 which is located below the gate electrode GE or the gate insulating layer 99 which serves as a mask. For example, as illustrated in FIG. 15A, the resistance is lowered to a portion located below the gate electrode GE (a portion of the channel region 97c) to be a low resistance region LR. As a result, an effective channel length (in this example, length in a channel length direction of a portion of the channel region 97c where the resistance is not lowered) L′ may be smaller than a design value (length defined by a width of the gate electrode GE) L (shortening of channel). This causes an off-current of the TFT 900 to increase and a threshold value voltage to be negative (depletion).

In order to prevent the shortening of the channel, for example, a structure is conceivable in which the width of the gate insulating layer 99 is enlarged to prevent the resistance of the channel region 97c from being lowered.

FIG. 15B is a cross-sectional view of an oxide semiconductor TFT 901 of Reference Example 2 having a top gate structure. In Reference Example 2, the gate insulating layer 99 and the gate electrode GE are separately patterned, and the width of the gate insulating layer 99 is wider than that of the gate electrode GE. Therefore, when the resistance lowering treatment of the oxide semiconductor layer 97 is performed using the gate insulating layer 99 and the gate electrode GE as a mask, high resistance regions 97r are formed on both sides of the channel region 97c.

In the present specification, a region 97r that is located between the channel region (that is, a region where overlaps the gate electrode GE when viewed from the normal direction of the main surface of the substrate 1) 97c and the first region 97s or the second region 97d where is the low resistance region LR (low resistance region for contacting the source electrode SE or the drain electrode DE) and has a higher resistivity than that of the low resistance region LR is referred to as a “channel offset region”. The resistivity of the channel offset region 97r may be approximately the same as the resistivity of the channel region 97c. The width of each channel offset region 97r in the channel length direction is referred to as a “channel offset length”.

In the TFT 901 of Reference Example 2, since the resistance of the channel region 97c is prevented from being lowered, the shortening of the channel is unlikely to occur. However, as illustrated in the drawing, in the resistance lowering treatment, the resistance of the oxide semiconductor layer 97, which is located below the gate insulating layer 99, may be lowered. As a result, a substantial channel offset length Loff′ may be smaller than a design value (length defined by the width of the gate insulating layer 99) Loff. Therefore, desired TFT characteristics may not be stably obtained. In the TFT 901, since the gate insulating layer 99 is patterned using a photomask different from that of the gate electrode GE, there is also a problem in that a photomask needs to be added and the manufacturing cost is increased.

As a result of a study based on the above findings, the present inventors found that a high resistance channel offset region having a predetermined width can be formed on both sides of the channel region by using an upper insulating layer by providing an insulating layer (hereinafter, “upper insulating layer”) made of a photosensitive spin-on-glass (SOG) material or a photosensitive resin so as to cover the gate electrode, and conceived the present invention.

As described above, a portion of the oxide semiconductor layer located below the gate insulating layer may be lowered in resistance by the resistance lowering treatment. On the other hand, since the upper insulating layer can be formed to be thicker than the gate insulating layer, the portion of the oxide semiconductor layer located below the upper insulating layer is not lowered in resistance by the resistance lowering treatment, and remains as a high resistance region (offset region). The length of the offset region can be controlled by adjusting the length of the upper insulating layer in the channel length direction. Therefore, according to an embodiment of the present invention, an active matrix substrate provided with an oxide semiconductor TFT capable of including a predetermined channel length L and a predetermined channel offset length Loff is provided by using the upper insulating layer. By using the photomask for forming the gate electrode for forming the upper insulating layer, it is possible to suppress an increase in the number of photomasks used and manufacturing cost.

### First Embodiment

Hereinafter, an active matrix substrate according to a first embodiment will be described with reference to the drawings.

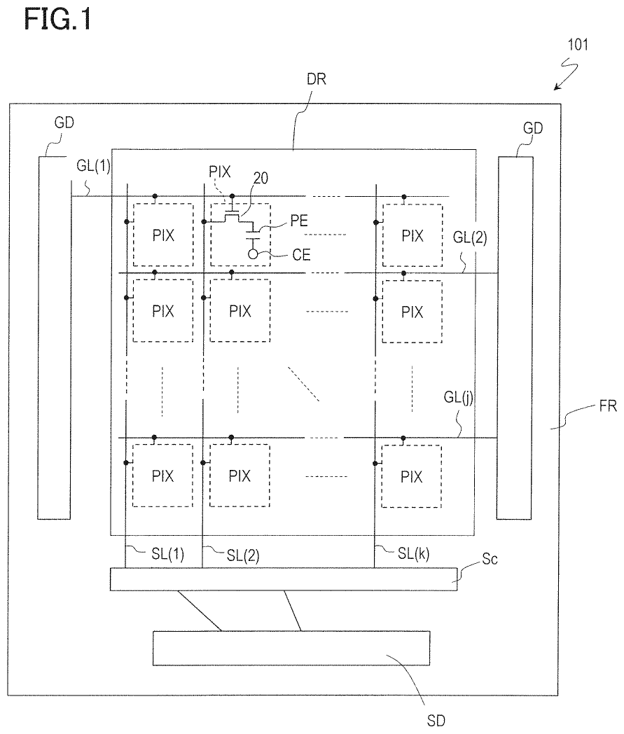

FIG. 1 is a diagram schematically illustrating an example of a planar structure of an active matrix substrate 101. The active matrix substrate 101 includes a display region DR contributing to display and a peripheral region (frame region) FR located outside the display region DR. The display region DR includes a plurality of pixel regions PIX arranged in a matrix. The pixel region PIX (simply, may be referred to as “pixel”) is a region corresponding to a pixel of the display device. The non-display region FR is a region located around the display region DR and does not contribute to display.

In the display region DR, the active matrix substrate 101 is provided with a substrate 1, a plurality of pixel TFTs 20 supported by the substrate 1, a plurality of pixel electrodes PE, a plurality of gate bus lines GL(1) to GL(j) for supplying the gate signal to the pixel TFT 20 (j is an integer of 2 or more, and hereinafter, collectively referred to as “gate bus line GL”), and a plurality of source bus lines SL(1) to SL(k) for supplying the source signal to the pixel TFT 20 (k is an integer of 2 or more, and hereinafter, collectively referred to as “source bus line SL”). Each pixel region PIX is defined by, for example, the gate bus line GL and the source bus line SL. The source bus line SL extends in a direction intersecting with the gate bus line GL.

Each pixel TFT 20 and each pixel electrode PE are provided corresponding to one of the plurality of pixel regions PIX. The gate electrode of the pixel TFT 20 is electrically connected to one of the gate bus lines GL, and the source electrode is electrically connected to one of the source bus lines SL. The drain electrode is electrically connected to the pixel electrode PE.

In a case where the active matrix substrate 101 is applied to a display device of a horizontal electric field mode such as a fringe field switching (FFS) mode, the active matrix substrate 101 is provided with a common electrode CE for a plurality of pixels PIX.

In the non-display region FR, a peripheral circuit such as a driver can be provided. For example, a gate driver GD that drives the gate bus line GL, an SSD circuit Sc that drives the source bus line SL in a time-division manner, and the like may be monolithically formed. The SSD circuit Sc is connected to a source driver SD implemented by, for example, a chip on glass (COG) method.

<Pixel Region PIX>

Next, a structure of the pixel region PIX of the active matrix substrate of the present embodiment will be described using an active matrix substrate applied to an FFS mode display device as an example with reference to the drawings. The FFS mode is a lateral electric field mode in which a pair of electrodes is provided on one substrate and an electric field is applied to liquid crystal molecules in a direction (lateral direction) parallel to a substrate surface.

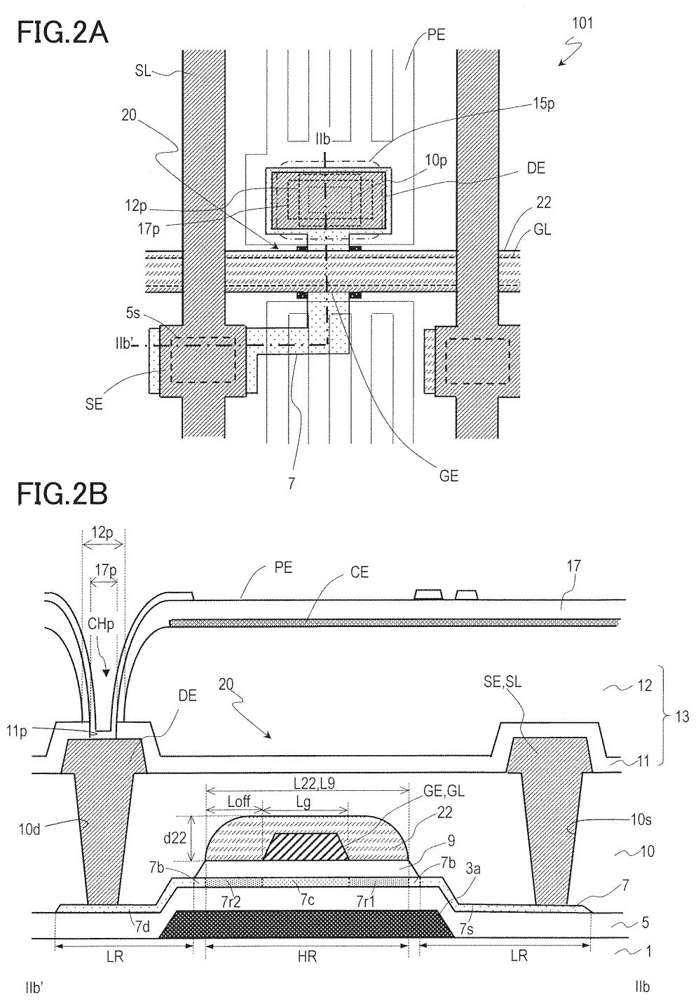

FIG. 2A is a plan view illustrating each pixel region PIX in the active matrix substrate 101, and FIG. 2B is a cross-sectional view taken along line IIb-IIb′ across the TFT 20 in the pixel region PIX.

The active matrix substrate 101 includes a substrate 1 and a plurality of source bus lines SL and a plurality of gate bus lines GL supported on a main surface of the substrate 1. Each pixel region PIX is defined by one source bus line SL and one gate bus line GL. Each pixel region PIX has a top gate type TFT 20, a pixel electrode PE, and a common electrode CE.

The TFT 20 includes an oxide semiconductor layer 7, a gate insulating layer 9 disposed on a portion of the oxide semiconductor layer 7, a gate electrode GE disposed on a portion of the gate insulating layer 9, a source electrode SE, and a drain electrode DE. The gate electrode GE is disposed so as to overlap a portion (channel region) 7c of the oxide semiconductor layer 7 via the gate insulating layer 9.

The oxide semiconductor layer 7 includes a channel region 7c overlapping the gate electrode GE, a first region 7s and a second region 7d respectively located on both sides of the channel region 7c, a first channel offset region 7r1 located between the channel region 7c and the first region 7s, and a second channel offset region 7r2 located between channel region 7c and second region 7d, when viewed from the normal direction of the main surface of the substrate 1. The first region 7s may be electrically connected to the corresponding source bus line SL via the source electrode SE. The second region 7d is electrically connected to the pixel electrode PE via the drain electrode DE. The first region 7s and the second region 7d are the low resistance regions having a lower resistivity than that of the channel region 7c. The first region 7s and the second region 7d may be conductor regions. The first channel offset region 7r1 and the second channel offset region 7r2 have the same resistivity as that of the channel region 7c. In the present specification, a region having a higher resistivity than that of the low resistance region LR, and including the channel region 7c, the first channel offset region 7r1, and the second channel offset region 7r2 is referred to as a “high resistance region HR”.

The gate electrode GE is formed using the same conductive film (gate conductive film) as that of the gate bus line GL. In the present specification, a layer including an electrode and wiring formed using the gate conductive film is referred to as a “gate metal layer”. The gate electrode GE may be formed integrally with (may be connected to) the gate bus line GL. For example, the gate electrode GE may be a portion of the gate bus line GL. In this case, a portion of the gate bus line GL that overlaps the oxide semiconductor layer 7 when viewed from the normal direction of the substrate 1 may be referred to as a “gate electrode GE”. Alternatively, when viewed from the normal direction of the substrate 1, the gate electrode GE may be formed in an extended portion or a protruding portion (branch portion) extending from a portion of the side surface of the gate bus line GL in a direction different from the gate bus line GL.

The gate electrode GE and the gate bus line GL are covered with the upper insulating layer 22 made of a photosensitive SOG or a photosensitive resin. The upper insulating layer 22 may have a pattern one size larger than the gate electrode GE and the gate bus line GL. In this example, the upper insulating layer 22 is in direct contact with the side surfaces and upper surfaces of the gate electrode GE and the gate bus line GL, and the upper surface of the gate insulating layer 9 (portion of the upper surface of the gate insulating layer 9 located around the gate electrode GE and the like). The upper insulating layer 22 is not in direct contact with the oxide semiconductor layer 7. As described later, the upper insulating layer 22 can be formed by exposing and developing using the photomask used for patterning the gate conductive film, for example.

The upper insulating layer 22 is disposed so as to overlap the high resistance region HR, that is, the channel region 7c, the first channel offset region 7r1, and the second channel offset region 7r2, and so as not to overlap the low resistance region LR, that is, the first region 7s and the second region 7d, when viewed from the normal direction of the substrate 1.

A length L22 of the upper insulating layer 22 in the channel length direction is larger than a length Lg of the gate electrode GE in the channel length direction. The length L22 of the upper insulating layer 22 in the channel length direction may be substantially the same as a length L9 of the upper surface of the gate insulating layer 9 in the channel length direction. When the side surface of the gate insulating layer 9 has a tapered shape, a tapered portion of the gate insulating layer 9 may be exposed from the upper insulating layer 22, when viewed from the normal direction of the substrate 1.

The thickness d22 of the upper insulating layer 22 may be larger than the thickness of the gate electrode GE and is not particularly limited. For example, the thickness is 300 nm or more and 1,000 nm or less. When it is 300 nm or more, it can more reliably function as a mask in the resistance lowering treatment and can protect the surface of the gate electrode GE. When it is 1,000 nm or less, a step due to the upper insulating layer 22 does not become too large.

When viewed from the normal direction of the substrate 1, a peripheral edge of the gate insulating layer 9 (peripheral edge of the upper surface of the gate insulating layer 9 when the gate insulating layer 9 has a tapered shape) may be coincided with the peripheral edge of the upper insulating layer 22. Such a structure can be obtained by patterning the gate insulating layer 9 using the upper insulating layer 22 as a mask.

In the illustrated example, the channel region 7c of the oxide semiconductor layer 7 overlaps the gate electrode GE, the gate insulating layer 9, and the upper insulating layer 22 when viewed from the normal direction of the substrate 1. The first region 7s and the second region 7d do not overlap any of the gate electrode GE, the gate insulating layer 9, and the upper insulating layer 22. The first channel offset region 7r1 and the second channel offset region 7r2 do not overlap the gate electrode GE, and overlap the upper insulating layer 22.

In this example, the gate insulating layer 9 has a tapered portion, and the tapered portion is exposed from the upper insulating layer 22. Therefore, when viewed from the normal direction of the substrate 1, the oxide semiconductor layer 7 does not overlap the gate electrode GE and the upper insulating layer 22 and has a region (inclined region) 7b overlapping only the tapered portion of the gate insulating layer 9. The inclined region 7b may be the low resistance region LR or the high resistance region HR. Alternatively, it may have a resistivity between the low resistance region LR and the high resistance region HR.

The oxide semiconductor layer 7, the gate insulating layer 9, the upper insulating layer 22, and the gate electrode GE are covered with the first interlayer insulating layer 10. As the first interlayer insulating layer 10, a reducing insulating film (for example, silicon nitride film) that can reduce an oxide semiconductor may be used. AS a result, it is possible to suppress an increase in the resistivity of the portions (first region 7s and second region 7d) of the oxide semiconductor layer 7 that are in contact with the first interlayer insulating layer 10. In the first interlayer insulating layer 10, a source opening portion 10s exposing a portion of the first region 7s and a drain opening portion 10d exposing a portion of the second region 7d are formed.

The source electrode SE is formed on the first interlayer insulating layer 10 and in the source opening portion 10s, and is connected to the first region 7s of the oxide semiconductor layer 7 in the source opening portion 10s. The drain electrode DE is formed on the first interlayer insulating layer 10 and in the drain opening portion 10d, and is connected to the second region 7d of the oxide semiconductor layer 7 in the drain opening portion 10d. The source electrode SE and the drain electrode DE may be formed using the same conductive film as that of the source bus line SL. The source electrode SE may be formed integrally with (may be connected to) the source bus line SL. For example, the source electrode SE may be a portion of the source bus line SL. In this case, a portion of the source bus line SL connected to the oxide semiconductor layer 7 may be referred to as a “source electrode SE”. Alternatively, when viewed from the normal direction of the substrate 1, the source electrode SE may be formed in an extended portion or a protruding portion (branch portion) extending from a portion of the side surface of the source bus line SL extending in the second direction in another direction.

The oxide semiconductor layer 7 may be provided on the lower insulating layer 5 formed on the main surface of the substrate 1. The light shielding layer 3a may be disposed between the lower insulating layer 5 and the substrate 1. The light shielding layer 3a is disposed so as to at least partially (preferably entirely) overlap the channel region 7c of the TFT 20 when viewed from the normal direction of the substrate 1. As illustrated in the drawing, when viewed from the normal direction of the substrate 1, the light shielding layer 3a may overlap the entire high resistance region HR (that is, the channel region 7c, the first channel offset region 7r1, and the second channel offset region 7r2) of the oxide semiconductor layer 7. As a result, deterioration of characteristics of the oxide semiconductor layer 7 due to light (backlight light) from the substrate 1 side can be suppressed more effectively.

The light shielding layer 3a may function as a lower electrode of the TFT 20. For example, the light shielding layer 3a may be electrically connected to the gate electrode GE (or corresponding gate bus line GL). Alternatively, the light shielding layer 3a may be fixed to a fixed potential (for example, source potential).

In the present specification, a layer located closer to the substrate 1 side than the oxide semiconductor layer 7 and including an electrode and/or a wiring formed of a conductive film (lower conductive film) may be referred to as a “lower metal layer”. A layer located above the gate electrode (top gate) and including an electrode and/or wiring formed of a conductive film (upper conductive film) may be referred to as an “upper metal layer”. In the illustrated example, the lower metal layer includes the light shielding layer (or lower electrode) 3a of the oxide semiconductor TFT 20, and the upper metal layer includes the source electrode SE, the drain electrode DE, and the source bus line SL of the oxide semiconductor TFT 20. As in this example, a substrate structure in which the source bus line SL is disposed above the gate bus line GL and the gate electrode GE may be referred to as an “upper source structure”. As described later, the source bus line SL and the source electrode SE of the oxide semiconductor TFT may be formed in the lower metal layer. A substrate structure in which the source bus line SL is disposed closer to the substrate 1 side than the gate bus line GL and the gate electrode is referred to as a “lower source structure”. In the lower source structure, the upper metal layer may include the drain electrode of the oxide semiconductor TFT. Alternatively, the pixel electrode may be directly connected to the oxide semiconductor layer without forming the drain electrode.

A second interlayer insulating layer 13 is formed on the upper metal layer including the source bus line SL so as to cover the TFT 20. For example, the second interlayer insulating layer 13 includes an inorganic insulating layer (passivation film) 11. As illustrated in the drawing, the second interlayer insulating layer 13 may have a stacked structure including the inorganic insulating layer 11 and an organic insulating layer 12 formed on the inorganic insulating layer 11. The organic insulating layer 12 may not be formed. Alternatively, the organic insulating layer 12 may be formed only in the display region.

A common electrode CE is formed on the second interlayer insulating layer 13. The common electrode CE may not be insulated for each pixel region PIX. For example, the common electrode CE may have an opening portion 15p in a region (pixel contact region) where a pixel contact hole CHp is formed, and may be formed over the entire pixel region PIX except for the pixel contact region.

The pixel electrode PE is disposed on the common electrode CE via a dielectric layer 17. The pixel electrode PE is insulated for each pixel region PIX. In each pixel region PIX, the pixel electrode PE is provided with one or a plurality of slits (opening portions) or a cutout portion.

The pixel electrode PE is disposed on the dielectric layer 17 and is connected to the second region 7d of the oxide semiconductor layer 7 in the pixel contact hole CHp formed in the second interlayer insulating layer 13 and the dielectric layer 17. The pixel contact hole CHp includes an opening portion 11p of the inorganic insulating layer 11, an opening portion 12p of the organic insulating layer 12, and an opening portion 17p of the dielectric layer 17. The opening portion 17p is at least partially overlapped the opening portion 12p when viewed from the normal direction of the substrate 1.

The opening portion 11p and the opening portion 17p may be formed by collectively etching the dielectric layer 17 and the inorganic insulating layer 11 using the resist mask on the dielectric layer 17 and the organic insulating layer 12 as a mask. In this case, in the pixel contact hole CHp, the side surface of the opening portion 11p can be coincided with the opening portion 17p or the opening portion 12p.

Although the pixel electrode PE is formed on the common electrode CE via the dielectric layer 17 in the illustrated example, the common electrode CE may be formed on the pixel electrode PE via the dielectric layer 17.

In the TFT 20 of the present embodiment, the channel offset regions 7r1 and 7r2 having a desired length (channel offset length Loff) can be formed on both sides of the channel region 7c in a cross section along the channel length direction of the oxide semiconductor layer 7. In the TFT 20, the channel offset regions 7r1 and 7r2, which are the high resistance regions HR, function as resistance regions, so that depletion of the TFT 20 can be suppressed more reliably.

As described above, in the TFT 901 having the top gate structure of Reference Example 2, the resistance is lowered to the portion located below the gate electrode GE or the gate insulating layer 9 of the oxide semiconductor layer 7, so that a predetermined channel offset length can not be ensured. As a result, desired TFT characteristics may not be obtained. On the other hand, in the present embodiment, by controlling the length L22 of the upper insulating layer 22, a predetermined channel offset length (length of each channel offset region 7r1 and 7r2 in the channel length direction) Loff can be secured. Therefore, it is possible to stably realize desired TFT characteristics.

As described later, the upper insulating layer 22 may be formed again by using the photomask used when forming the gate metal layer. AS a result, the TFT 20 having the above structure can be manufactured without increasing the manufacturing cost.

It is also conceivable to form the channel offset region by forming an insulating layer having a predetermined width (thickness) by etching back only on the side surface of the gate electrode. However, in a high-definition active matrix substrate, the size of the pixel TFT is minute, and it is difficult to form an insulating layer having a sufficient thickness on the side surface of the gate electrode by etching back. Since the active matrix substrate normally has multiple steps, there is a possibility that an unnecessary insulating layer may be formed on the side surface of the gate electrode due to the etching back. On the other hand, in the present embodiment, since the upper insulating layer 22 is formed so as to cover the upper surface and the side surface of the gate electrode GE by a method different from the etching back, the above problem does not occur. Furthermore, since the entire surface (not only the side surface but also the upper surface) of the gate electrode GE is covered with the upper insulating layer 22, the surface of the gate electrode GE can be protected. For example, when the surface of the gate electrode GE contains Cu, Cu oxidation due to process damage can be suppressed.

<Method for Forming Gate Metal Layer and Upper Insulating Layer 22>

In the present embodiment, the gate electrode GE (or gate metal layer) and the upper insulating layer 22 may be formed using the same photomask.

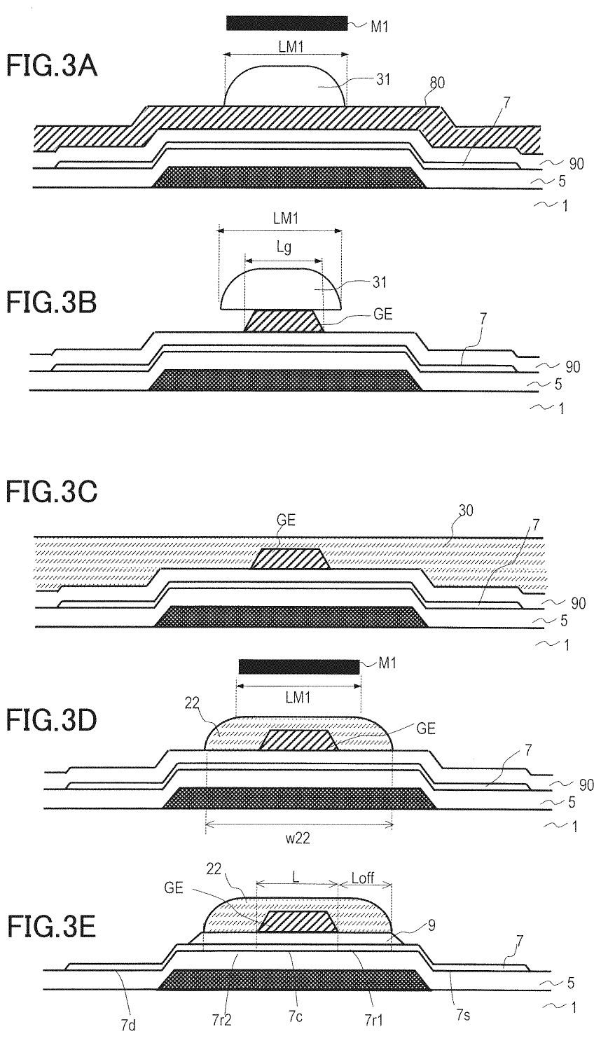

FIGS. 3A to 3E are step sectional views illustrating an example of a step of forming the gate electrode GE and the upper insulating layer 22. In this example, in accordance with a design value of the channel length of the TFT (length of the channel region 7c, that is, length Lg of the gate electrode GE in the channel length direction), a width LM1 of a photomask M1 (in the case of a positive type, width of light shielding portion) is set.

First, a light shielding layer 3a, a lower insulating layer 5, an oxide semiconductor layer 7, a gate insulating film 90, a gate conductive film 80, and a resist film are formed in this order on the substrate 1. Next, as illustrated in FIG. 3A, a resist layer 31 is formed on the gate conductive film 80 by exposing and developing the resist film using the photomask M1. The width of the resist layer 31 in the channel length direction is substantially the same as the width LM1 of the photomask.

Next, as illustrated in FIG. 3B, the gate conductive film 80 is etched using the resist layer 31 as a mask to form a gate metal layer including the gate electrode GE and the gate bus line GL (not illustrated). At this time, the etching time may be set long (over-etching) so that the length Lg of the gate electrode GE in the channel length direction is smaller than the width LM1 of the photomask M1 (width of the resist layer 31). Thereafter, the resist layer 31 is removed.

Subsequently, as illustrated in FIG. 3C, a photosensitive SOG film 30 is formed by coating so as to cover the gate electrode GE. The photosensitive SOG film 30 is a coating type oxide film (SiO₂ film). The photosensitive SOG film 30 can be formed using a known material. Regarding the material of the photosensitive SOG film, the entire disclosure of International Publication No. 2012/161025 is incorporated herein by reference.

Next, as illustrated in FIG. 3D, the photomask M1 used in FIG. 3A is used again, and the photosensitive SOG film 30 is exposed, developed, and baked to obtain an upper insulating layer 22. Here, the photosensitive SOG film 30 is exposed under the condition that the length L22 of the upper insulating layer 22 in the channel length direction is larger than the width LM1 of the photomask M1. For example, when a positive photosensitive SOG film 30 is used, the line width can be increased by decreasing the exposure amount. As described above, the upper insulating layer 22 can be formed so as to cover the gate electrode GE and the gate bus line GL.

Subsequently, as illustrated in FIG. 3E, the gate insulating film 90 is patterned using the upper insulating layer 22 as a mask to obtain a gate insulating layer 9. When viewed from the normal direction of the substrate 1, the peripheral edge of the upper insulating layer 22 and the peripheral edge of the gate insulating layer 9 (peripheral edge of the upper surface of the gate insulating layer 9 when the gate insulating layer 9 has a tapered shape) are coincided with each other.

Thereafter, the resistance lowering treatment of the oxide semiconductor layer 7 is performed using the upper insulating layer 22 as a mask (or using the upper insulating layer 22 and the gate insulating layer 9 as a mask). As a result, the resistivity of the region of the oxide semiconductor layer 7 exposed from the upper insulating layer 22 can be lower than the resistivity of the region covered with the upper insulating layer 22.

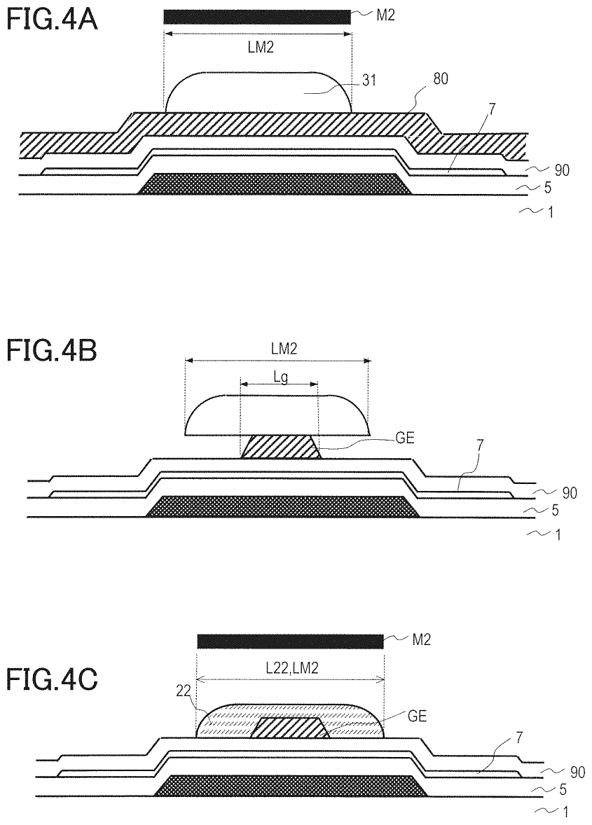

FIGS. 4A to 4C are step sectional views illustrating another example of the step of forming the gate electrode GE and the upper insulating layer 22. In this example, a width LM2 of the photomask M2 is set according to the design value of the length of the high resistance region HR in the oxide semiconductor layer 7 (that is, length L22 of the upper insulating layer 22).

First, as illustrated in FIG. 4A, a gate insulating film 90, a gate conductive film 80, and a resist film are formed by the same method as that of FIG. 3A, and thereafter a resist layer 31 is formed. The width of the resist layer 31 in the channel length direction is substantially the same as the width LM2 of the photomask M2.

Next, as illustrated in FIG. 4B, the gate conductive film 80 is etched using the resist layer 31 as a mask. At this time, the etching conditions are adjusted such that the length Lg of the gate electrode GE is sufficiently smaller than the width LM2 of the photomask M2 (width of the resist layer 31) (for example, etching time is extended to increase the over-etching time). As a result, the gate electrode GE having the predetermined width Lg is obtained. Thereafter, the resist layer 31 is removed.

Subsequently, a photosensitive SOG film (or photosensitive resin film) is formed so as to cover the gate electrode GE. Thereafter, as illustrated in FIG. 4C, the photomask M2 is used again, the photosensitive SOG film is exposed and developed to obtain an upper insulating layer 22. The width L22 of the upper insulating layer 22 may be approximately the same as the width LM2 defined by the photomask M2.

Thereafter, although not illustrated, the gate insulating film 90 is etched using the upper insulating layer 22 as a mask by the same method as that illustrated in FIG. 3E, and thereafter the resistance lowering treatment of the oxide semiconductor layer 7 is performed.

According to the method illustrated in FIGS. 3A to 3E and 4A to 4C, the gate metal layer and the upper insulating layer 22 are patterned using the same photomask, and the gate insulating layer 9 is patterned using the upper insulating layer 22 as a mask. Therefore, high resistance channel offset regions 7r1 and 7r2 having a predetermined width (channel offset length Loff) can be formed on both sides of the channel region 7c without increasing the number of photomasks used.

The channel length L is determined by the length Lg of the gate electrode GE in the above method. The channel offset length Loff corresponds to the length along the channel length direction between the end portion of the gate electrode GE and the end portion of the upper insulating layer 22, and is determined by the length L22 of the upper insulating layer 22 and the length Lg of the gate electrode GE. Therefore, the channel length L and the channel offset length Loff can be controlled by adjusting the process conditions when patterning the gate conductive film 80 and the photosensitive SOG film 30. For example, the channel length L may be 2 μm or more and 10 μm or less. The channel offset length Loff is not particularly limited, and may be, for example, 0.3 μm or more and 1 μm or less. When it is 0.3 μm or more, depletion can be suppressed more effectively. On the other hand, when it is 1 μm or less, an increase in on-resistance can be suppressed.

A photosensitive resin film may be used instead of the photosensitive SOG film 30. However, since the photosensitive resin film contains a large amount of water, the TFT characteristics may be affected by the entry of water into the oxide semiconductor layer 7 or the like. The photosensitive resin film may be oxidized and colored when exposed to a high temperature of 250° C. or higher. On the other hand, the photosensitive SOG film 30 absorbs less water than the photosensitive resin film and is formed by high-temperature baking, so that the above problems are unlikely to occur.

<Wiring Connecting Portion (Lower Electrode Connecting Portion)>

When the light shielding layer 3a of the TFT 20 functions as a “lower electrode”, the active matrix substrate 101 may further include a lower electrode connecting portion that connects the lower electrode to a wiring in a metal layer other than the lower metal layer. In the lower electrode portion, the light shielding layer (lower electrode) 3a may be electrically connected to the gate bus line or the source bus line. The lower electrode connecting portion may be disposed corresponding to each pixel region in the display region.

In the present specification, a connecting portion, such as a lower electrode connecting portion, that electrically connects electrodes and wirings formed in different metal layers (conductive layers) may be collectively referred to as a “wiring connecting portion”. The wiring connecting portion may include a terminal portion disposed in the non-display region, a source-gate connecting portion, and the like, in addition to the lower electrode connecting portion.

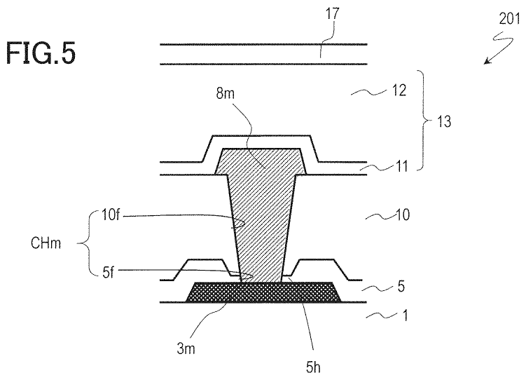

FIG. 5 is a cross-sectional view illustrating the lower electrode connecting portion 201.

In this example, the lower electrode connecting portion 201 connects the lower conductive layer 3m formed (in the lower metal layer) using the same conductive film as that of the light shielding layer 3a and the upper conductive layer 8m formed (in the upper metal layer) using the same conductive film as that of the source bus line SL The lower conductive layer 3m is connected to the light shielding layer 3a. The upper conductive layer 8m may be connected to the source bus line SL or may be a portion of the source bus line SL, for example. The lower electrode connecting portion 201 may be disposed so as to overlap the source bus line SL when viewed from the normal direction of the substrate 1, for example.

The lower insulating layer 5 and the first interlayer insulating layer 10 extend on the lower conductive layer 3m. The contact hole CHm exposing a portion of the lower conductive layer 3m is formed in the lower insulating layer 5 and the first interlayer insulating layer 10. The upper conductive layer 8m is disposed on the first interlayer insulating layer 10 and in the contact hole CHm, and is connected to the lower conductive layer 3m in the contact hole CHm. The contact hole CHm includes an upper opening portion 10f formed in the first interlayer insulating layer 10 and a lower opening portion 5f formed in the lower insulating layer 5. As illustrated in the drawing, the lower insulating layer 5 may include a thin film portion 5h on the lower conductive layer 3m, which is thinner than the other portions, and the lower opening portion 5f may be formed in the thin film portion 5h.

<Method for Manufacturing Active Matrix Substrate 101>

Hereinafter, an example of a method for manufacturing the active matrix substrate according to the present embodiment will be described with reference to the drawings.

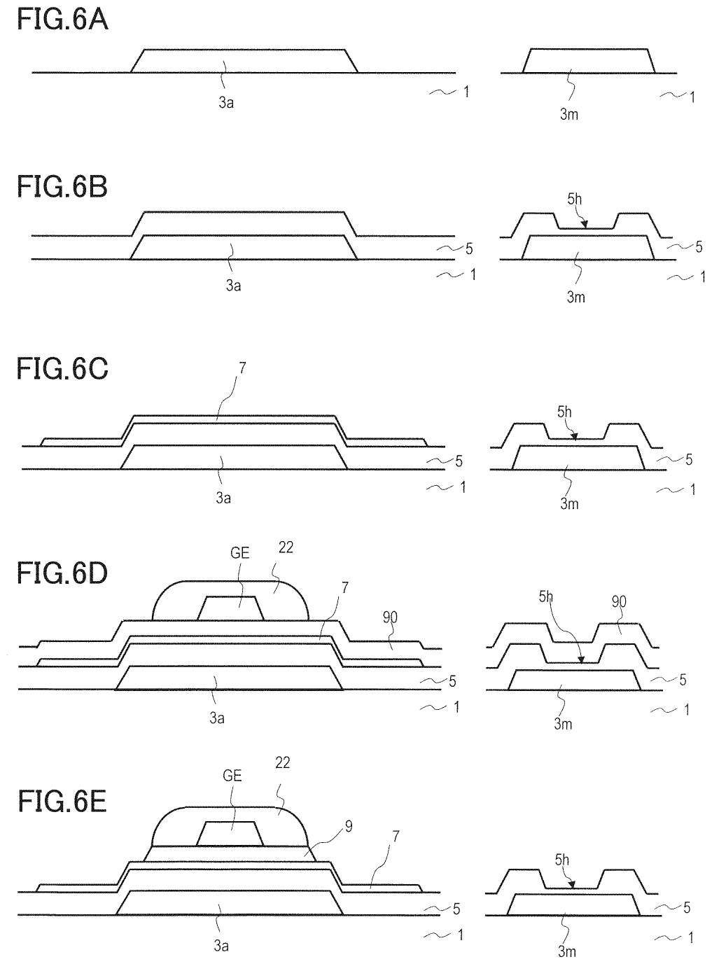

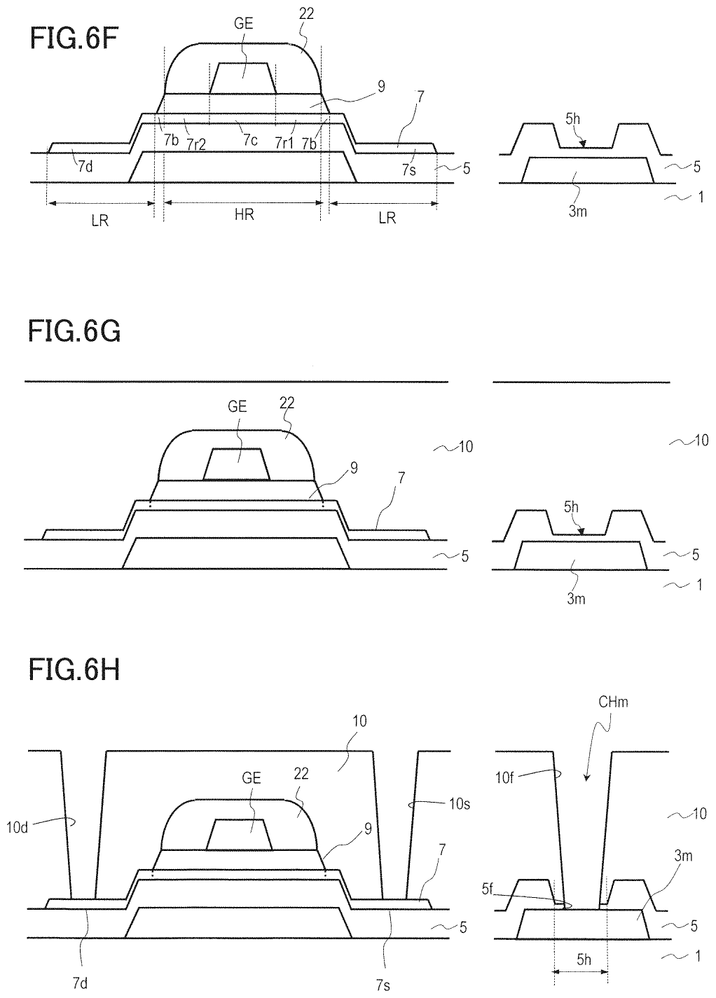

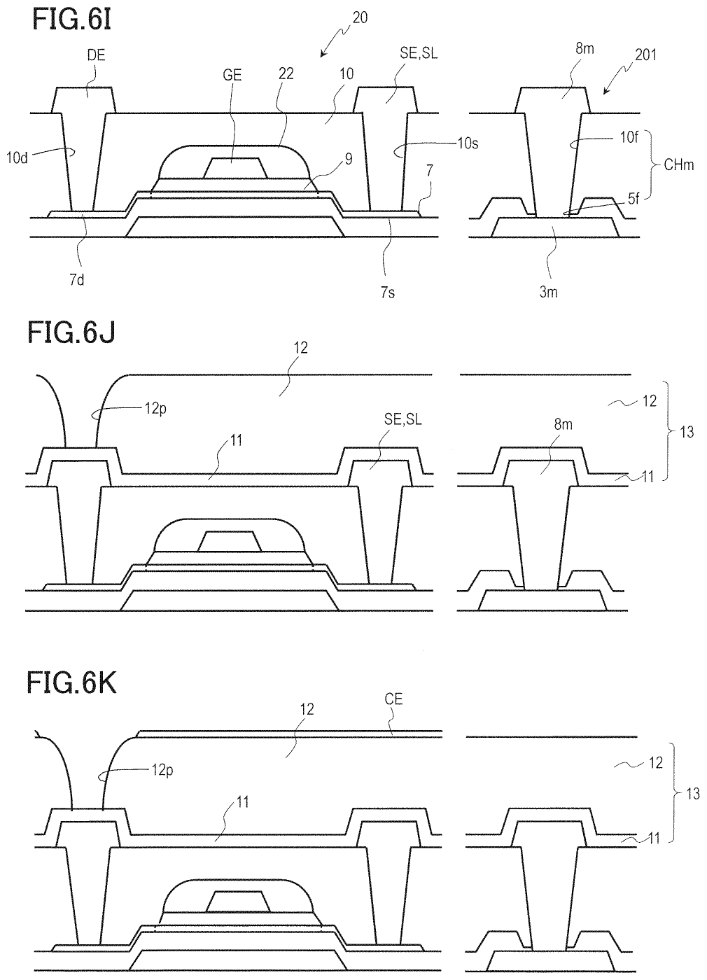

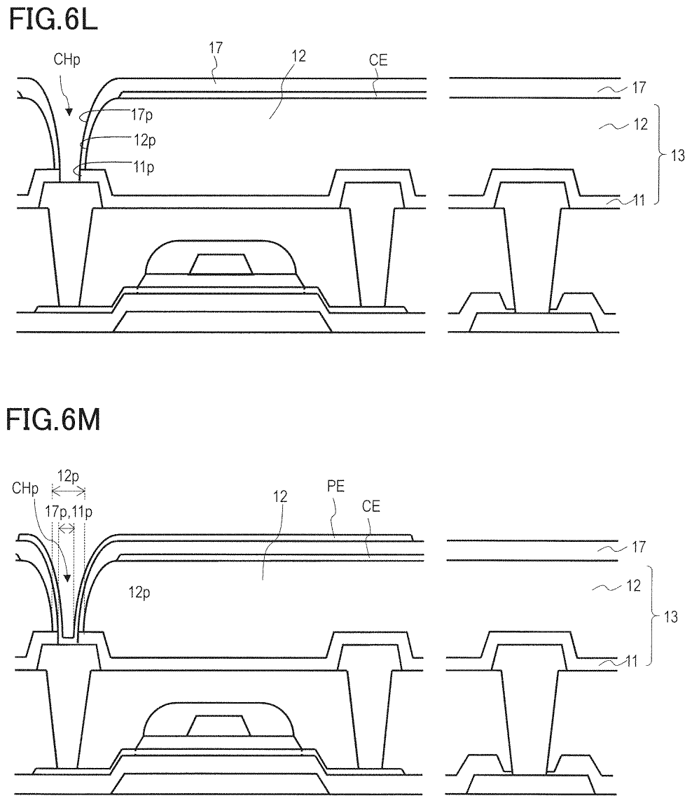

FIGS. 6A to 6M are schematic step sectional views for describing an example of the method for manufacturing the active matrix substrate 101, and illustrate forming regions of the TFT 20 and the lower electrode connecting portion 201.

STEP 1: Formation of Lower Metal Layer (FIG. 6A)

A lower conductive film (thickness: for example, 50 nm or more and 500 nm or less) is formed on the substrate 1 by, for example, a sputtering method. Next, patterning (for example, wet etching) of the lower conductive film is performed by a known photolithography step. As described above, as illustrated in FIG. 6A, the lower metal layer including the light shielding layer 3a and the lower conductive layer 3m of the lower electrode connecting portion is formed.

As the substrate 1, a transparent and insulating substrate, for example, a glass substrate, a silicon substrate, a plastic substrate (resin substrate) having heat resistance, or the like can be used.

The material of the lower conductive film is not particularly limited, and a film containing a metal such as aluminum (Al), tungsten (W), molybdenum (Mo), tantalum (Ta), chromium (Cr), titanium (Ti), or and copper (Cu), an alloy thereof, or a metal nitride thereof can be appropriately used. Alternatively, a stacked film in which a plurality of these films are stacked may be used. Here, a stacked film (Cu/Ti film) including a Ti film (thickness: 30 nm) and a Cu film (thickness: 200 nm) in this order from the substrate 1 side is used as the lower conductive film.

STEP 2: Formation of Lower Insulating Layer 5 (FIG. 6B)

Next, as illustrated in FIG. 6B, a lower insulating layer 5 (thickness: for example, 200 nm or more and 600 nm or less) is formed so as to cover the lower metal layer.

The lower insulating layer 5 is formed by, for example, a CVD method. As the lower insulating layer 5, a silicon oxide (SiOₓ) layer, a silicon nitride (SiNₓ) layer, a silicon oxynitride (SiOₓN_{y}; x>y) layer, a silicon nitride oxide (SiNₓO_{y}; x>y) layer, or the like can be appropriately used. The lower insulating layer 5 may be a single layer or may have a stacked structure. For example, a silicon nitride (SiNₓ) layer, a silicon nitride oxide layer, or the like may be formed on the substrate side (lower layer) to prevent diffusion of impurities and the like from the substrate 1, and a silicon oxide (SiO₂) layer, a silicon oxynitride layer, or the like may be formed on a layer thereover (upper layer) to secure insulation. Here, as the lower insulating layer 5, a stacked film having a silicon nitride (SiNₓ) layer (thickness: 50 to 600 nm) as a lower layer and a silicon oxide (SiO₂) layer (thickness: 50 to 600 nm) as an upper layer may be formed. When an oxide film such as a silicon oxide film is used as the lower insulating layer 5 (in a case where the lower insulating layer 5 has a stacked structure, as an uppermost layer), since oxidation deficiency generated in a channel region of an oxide semiconductor layer formed later can be reduced by the oxide film, reduction in resistance of the channel region can be suppressed.

Thereafter, half etching for thinning a portion of the lower insulating layer 5 is performed. AS a result, the thin film portion 5h is formed in the portion of the lower insulating layer 5 located on the lower conductive layer 3m. The thin film portion 5h is thinner than the other portions of the lower insulating layer 5. When viewed from the normal direction of the substrate 1, the thin film portion 5h is disposed so as to overlap a portion of the lower conductive layer 3m, for example. The thickness of the thin film portion 5h is not particularly limited, and may be 50 nm or more and 200 nm or less. When it is 50 nm or more, damage to the surface of the lower conductive layer 3m can be suppressed in a subsequent step of etching the oxide semiconductor film. When it is 200 nm or less, the first interlayer insulating layer and the thin film portion 5h can be collectively etched at a later step, more easily.

STEP 3: Formation of Oxide Semiconductor Layer 7 (FIG. 6C)

Subsequently, an oxide semiconductor film (not illustrated) is formed on the lower insulating layer 5. Thereafter, annealing treatment of the oxide semiconductor film may be performed. The thickness of the oxide semiconductor film may be, for example, 15 nm or more and 200 nm or less.

Subsequently, patterning of the oxide semiconductor film is performed by a known photolithography step. The oxide semiconductor film may be patterned by wet etching using a PAN-based etching solution containing phosphoric acid, nitric acid, and acetic acid, or an oxalic acid-based etching solution, for example. As a result, as illustrated in FIG. 6C, an oxide semiconductor layer 7 to be an active layer of the TFT 20 is obtained.

The oxide semiconductor film can be formed by, for example, a sputtering method. Here, an In—Ga—Zn—O-based semiconductor film (thickness: 50 nm) containing In, Ga, and Zn is formed as the oxide semiconductor film.

When the step of etching the oxide semiconductor film is performed using a PAN-based etching solution with the surface of the lower metal layer (for example, the surface containing Cu or Al) exposed, the exposed portion of the lower metal layer may also be etched. On the other hand, in this method, the surfaces of the lower metal layers (light shielding layer 3a and lower conductive layer 3m) are protected by the lower insulating layer 5 and are not exposed. Therefore, even when the oxide semiconductor film is patterned using a PAN-based etching solution, the lower metal layer is not etched.

STEP 4: Formation of Gate Insulating Layer 9, Gate Metal Layer, and Insulating Layer (FIGS. 6D and 6E)

Next, a gate insulating film (thickness: for example, 80 nm or more and 250 nm or less) 90 and a gate conductive film (not illustrated) (thickness: for example, 50 nm or more and 500 nm or less) are formed in this order so as to cover the oxide semiconductor layer 7.

As the gate insulating film 90, an insulating film similar to the lower insulating layer 5 (insulating film exemplified as the lower insulating layer 5) can be used. Here, a silicon oxide (SiO₂) layer is formed as the gate insulating film 90. When an oxide film such as a silicon oxide film is used as the insulating film, since oxidation deficiency generated in the channel region of the oxide semiconductor layer 7 can be reduced by the oxide film, reduction in resistance of the channel region can be suppressed.

As the gate conductive film, for example, a metal such as molybdenum (Mo), tungsten (W), aluminum (Al), copper (Cu), titanium (Ti), tantalum (Ta), or an alloy thereof can be used. The gate conductive film may have a stacked structure including a plurality of layers formed of different conductive materials. Here, as the gate conductive film, a Cu and Ti stacked film having a Ti film as a lower layer and a Cu film as an upper layer, or a Cu and Mo stacked film having a Mo film as a lower layer and a Cu film as an upper layer is used.

Thereafter, as illustrated in FIG. 6D, a gate metal layer including the gate electrode GE and the gate bus line GL is formed on the gate insulating film 90 by the method described above with reference to FIGS. 3A to 3E (or FIGS. 4A to 4C) and thereafter an upper insulating layer 22 is formed. Specifically, a photomask (not illustrated) is used to form a resist layer on the gate conductive film, and the gate conductive film is patterned to form a gate metal layer. When patterning the gate conductive film, the etching conditions may be adjusted so that the width of the gate electrode GE is smaller than the width of the resist layer. Next, the resist layer is removed, and a photosensitive SOG film (or photosensitive resin film) not illustrated is applied so as to cover the gate metal layer. Subsequently, using the above photomask again, the photosensitive SOG film is exposed, and thereafter developed and baked to obtain the upper insulating layer 22. The exposure condition of the photosensitive SOG film may be set such that the pattern width of the photosensitive SOG film is larger than the widths of the gate electrode GE and the gate bus line GL. The photosensitive SOG film is removed in a region where the gate metal layer does not exist, such as a forming region of the lower electrode connecting portion.

Next, as illustrated in FIG. 6E, the gate insulating film 90 is etched using the upper insulating layer 22 as a mask to obtain the gate insulating layer 9. As a result, portions of the oxide semiconductor layer 7 that are located on both sides of the region to be the channel and are not covered with the upper insulating layer 22 are exposed.

Step 5: Resistance Lowering Treatment and Formation of First Interlayer Insulating Layer 10 (FIGS. 6F to 6H)

Subsequently, resistance lowering treatment of the oxide semiconductor layer 7 may be performed. As the resistance lowering treatment, for example, a plasma treatment may be performed. As a result, as illustrated in FIG. 6F, when viewed from the normal direction of the main surface of the substrate 1, a region of the oxide semiconductor layer 7 that does not overlap the upper insulating layer 22 and the gate insulating layer 9 is a low resistance region LR having a lower resistivity than that of a region that overlaps the upper insulating layer 22 and the gate insulating layer 9. The low resistance region may be a conductor region (for example, sheet resistance: 200 Ω/or less). A region of the oxide semiconductor layer 7 that overlaps the upper insulating layer 22 and the gate insulating layer 9 is not lowered in resistance, remains as the semiconductor region, and is a high resistance region HR. When the side surface of the gate insulating layer 9 has a tapered shape, and viewed from the normal direction of the substrate 1, a region (inclined region) 7b of the oxide semiconductor layer 7 which does not overlap the upper insulating layer 22 and overlaps only the tapered portion of the gate insulating layer 9 may be the low resistance region LR, the high resistance region HR, or may have a resistivity between these regions.

The portions of the low resistance region LR located on both sides of the gate electrode GE are the first region 7s and the second region 7d, respectively. The high resistance region HR includes the channel region 7c that overlaps the gate electrode GE and the channel offset regions 7r1 and 7r2 that do not overlap the gate electrode GE when viewed from the normal direction of the substrate 1.

In the resistance lowering treatment (plasma treatment), a portion of the oxide semiconductor layer 7 that is not covered with the upper insulating layer 22 or the gate insulating layer 9 may be exposed to reducing plasma or plasma containing a doping element (for example, argon plasma). As a result, the resistance is reduced near the surface of the exposed portion of the oxide semiconductor layer 7, and the oxide semiconductor layer 7 is a low resistance region. A portion of the oxide semiconductor layer 7 which is masked by the upper insulating layer 22 or the gate insulating layer 9 remains as a semiconductor region. The method and conditions for the resistance lowering treatment are described in, for example, Japanese Unexamined Patent Application Publication No. 2008-40343. For reference, the entire content of the disclosure of Japanese Unexamined Patent Application Publication No. 2008-40343 is incorporated herein.

Next, as illustrated in FIG. 6G, a first interlayer insulating layer 10 covering the oxide semiconductor layer 7, the gate insulating layer 9, the gate metal layer, and the upper insulating layer 22 is formed. As the first interlayer insulating layer 10, an inorganic insulating layer such as a silicon oxide film, a silicon nitride film, a silicon oxynitride film, a silicon nitride oxide film, or the like can be formed as a single layer or a stacked layer. The thickness of the inorganic insulating layer may be 100 nm or more and 500 nm or less. When the first interlayer insulating layer 10 is formed using an insulating film such as a silicon nitride film that reduces an oxide semiconductor, this is preferable because the resistivity of a region (here, a low resistance region) in contact with the first interlayer insulating layer 10 in the oxide semiconductor layer 7 can be maintained low. Here, as the first interlayer insulating layer 10, for example, a stacked film having a SiO₂ layer as a lower layer and a SiNₓ layer as an upper layer is formed by a CVD method.

Thereafter, as illustrated in FIG. 6H, the first interlayer insulating layer 10 is patterned by dry etching, for example. AS a result, the source opening portion 10s exposing a portion of the first region 7s of the oxide semiconductor layer 7 and the drain opening portion 10d exposing a portion of the second region 7d are formed in the first interlayer insulating layer 10. The contact hole CHm is formed in the first interlayer insulating layer 10 and the lower insulating layer 5 so as to at least partially overlap the thin film portion 5h in the forming region of the lower electrode connecting portion. The contact hole CHm includes the upper opening portion 10f formed in the first interlayer insulating layer 10 and the lower opening portion 5f formed in the thin film portion 5h. In the contact hole CHm, the side surface of the upper opening portion 10f and the side surface of the lower opening portion 5f may be at least partially coincided with each other.

STEP 6: Formation of Upper Metal Layer (FIG. 6I)

Next, an upper conductive film (thickness: for example, 50 nm or more and 500 nm or less) is formed on the first interlayer insulating layer 10, and patterning of the upper conductive film is performed. AS a result, as illustrated in FIG. 6I, an upper metal layer including the source electrode SE, the source bus line SL, the drain electrode DE, and the upper conductive layer 8m of the lower electrode connecting portion is formed. The source electrode SE is disposed on the first interlayer insulating layer 10 and in the source opening portion 10s, and is connected to the first region 7s of the oxide semiconductor layer 7 in the source opening portion 10s. The drain electrode DE is disposed on the first interlayer insulating layer 10 and in the drain opening portion 10d, and is connected to the second region 7d of the oxide semiconductor layer 7 in the drain opening portion 10d. The upper conductive layer 8m is disposed on the first interlayer insulating layer 10 and in contact hole CHm, and is connected to the lower conductive layer 3m in the contact hole CHm. As described above, the lower electrode connecting portion 201 is obtained.

As the upper conductive film, for example, an element selected from aluminum (Al), chromium (Cr), copper (Cu), tantalum (Ta), titanium (Ti), molybdenum (Mo), or tungsten (W), or an alloy containing these elements as components can be used. For example, the upper conductive film may have a three-layer structure of a titanium film-aluminum film-titanium film, a three-layer structure of a molybdenum film-aluminum film-molybdenum film, or the like. Here, a stacked film in which a Ti film (thickness: 15 to 70 nm) is a lower layer and a Cu film (thickness: 200 to 400 nm) is an upper layer is used.

STEP 7: Formation of Inorganic Insulating Layer 11 and Organic Insulating Layer 12 (FIG. 6J)

Next, as illustrated in FIG. 6J, a second interlayer insulating layer 13 is formed so as to cover the first interlayer insulating layer 10 and the upper metal layer. Here, as the second interlayer insulating layer 13, an inorganic insulating layer 11 (thickness: for example, 100 nm or more and 500 nm or less) and an organic insulating layer 12 (thickness: for example, 1 to 3 μm, preferably 2 to 3 μm) are formed in this order. The entire portion of the organic insulating layer 12 located in the non-display region may be removed. Alternatively, the organic insulating layer 12 may not be formed.

As the inorganic insulating layer 11, the inorganic insulating film similar to the first interlayer insulating layer 10 (insulating film exemplified as the first interlayer insulating layer 10) can be used. Here, as the inorganic insulating layer 11, for example, a SiNₓ layer (thickness: 300 nm) is formed by a CVD method. The organic insulating layer 12 may be, for example, an organic insulating film (for example, acrylic resin film) containing a photosensitive resin material.

Thereafter, patterning of the organic insulating layer 12 is performed. As a result, in each pixel region PIX, an opening portion 12p exposing a portion of the inorganic insulating layer 11 is formed in the organic insulating layer 12. The opening portion 12p is disposed so as to overlap the drain electrode DE when viewed from the normal direction of the substrate 1.

STEP 8: Formation of Common Electrode CE (FIG. 6K)

Subsequently, as illustrated in FIG. 6K, the common electrode CE is formed on the second interlayer insulating layer 13.

First, a first transparent conductive film (not illustrated) (thickness: 20 to 300 nm) is formed on the second interlayer insulating layer 13 and in the opening portion 12p. Here, for example, an indium-zinc oxide film is formed as the first transparent conductive film by a sputtering method. As a material for the first transparent electrode film, a metal oxide such as indium-tin oxide (ITO), indium-zinc oxide, or ZnO can be used. Thereafter, patterning of the first transparent conductive film is performed. In patterning, for example, wet etching may be performed using an oxalic acid-based etching solution. As a result, the common electrode CE is obtained. The common electrode CE may be disposed, for example, over substantially the entire display region except for the pixel contact hole forming region where the pixel contact hole CHp is formed.

STEP 9: Formation of Dielectric Layer 17 (FIG. 6L)

Next, as illustrated in FIG. 6L, a dielectric layer (thickness: 50 to 500 nm) 17 is formed so as to cover the common electrode CE, and patterning of the dielectric layer 17 and the inorganic insulating layer 11 are performed.

The dielectric layer 17 is formed on the organic insulating layer 12 and the common electrode CE and in the opening portion 12p in the pixel region PIX. The material of the dielectric layer 17 may be the same as the material exemplified as the material of the inorganic insulating layer 11. Here, a SiN film is formed as the dielectric layer 17 by, for example, a CVD method.

Thereafter, a resist layer (not illustrated) formed on the dielectric layer 17 is formed by a photolithography step. Using the resist layer and the organic insulating layer 12 as a mask, the dielectric layer 17 and the inorganic insulating layer 11 are etched (for example, dry-etched). The etching of the dielectric layer 17 and the inorganic insulating layer 11 may be performed in the same etching step. As a result, a pixel contact hole CHp exposing a portion of the second region 7d of the oxide semiconductor layer 7 is formed in the pixel region PIX. The pixel contact hole CHp is configured to include the opening portion 11p formed in the inorganic insulating layer 11, the opening portion 12p in the organic insulating layer 12, and the opening portion 17p in the dielectric layer 17. The opening portion 17p may be at least partially overlapped the opening portion 12p when viewed from the normal direction of the substrate 1.

STEP 10: Formation of Pixel Electrode PE (FIG. 6M)

Subsequently, a second transparent conductive film (not illustrated) (thickness: 20 to 300 nm) is formed on the dielectric layer 17 and in the pixel contact hole CHp. The material of the second transparent conductive film may be the same as the material exemplified as the material of the second transparent conductive film (for example, ITO).

Thereafter, patterning of the second transparent conductive film is performed. For example, wet etching of the second transparent conductive film may be performed using an oxalic acid-based etching solution. As a result, as illustrated in FIG. 6M, a pixel electrode PE is obtained. The pixel electrode PE is formed on the dielectric layer 17 and in the pixel contact hole CHp in the pixel region PIX, and is in contact with the second region 7d in the pixel contact hole CHp. As described above, the active matrix substrate 101 is manufactured.

<Another Lower Electrode Connecting Portion>

The above lower electrode connecting portion 201 connects the light shielding layer (lower electrode) 3a of the TFT 20 to the source bus line SL, and may instead be configured to connect to the gate electrode GE (or gate bus line GL).

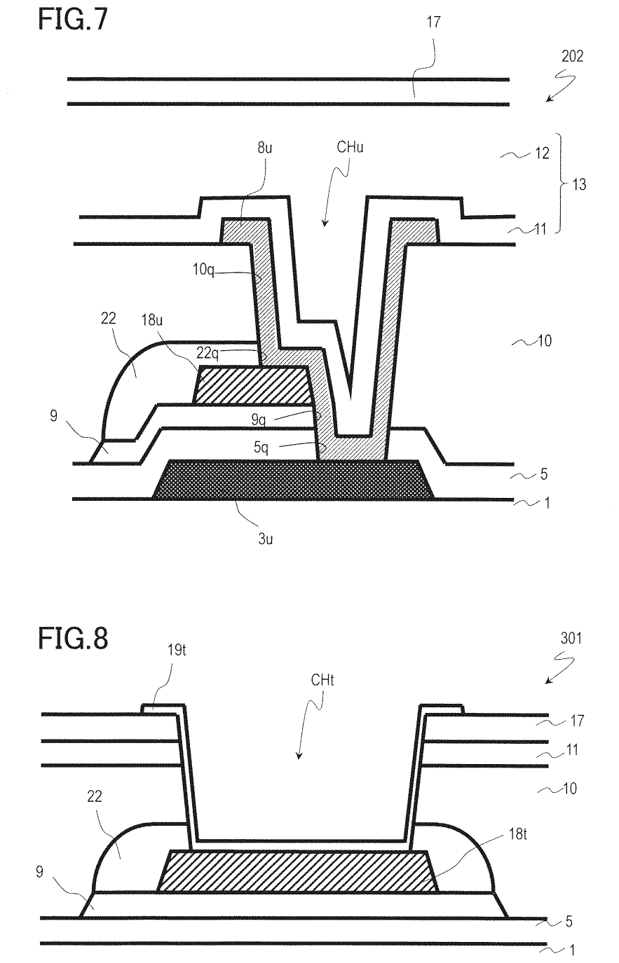

FIG. 7 is a cross-sectional view illustrating another lower electrode connecting portion 202.

In the lower electrode connecting portion 202, the light shielding layer 3a of the TFT 20 is electrically connected to the gate electrode GE (that is, gate bus line GL) via the source connecting layer 8u formed in the upper metal layer. For example, the lower electrode connecting portion 202 may be disposed so as to overlap a portion of the gate bus line GL.

The lower electrode connecting portion 202 is provided with the lower conductive layer 3u, the gate connecting layer 18u disposed on a portion of the lower conductive layer 3u via the lower insulating layer 5 and the gate insulating layer 9, the insulating layer that covers the gate connecting layer 18u (here, upper insulating layer 22 and first interlayer insulating layer 10), and the source connecting layer 8u disposed on the insulating layer.

The lower conductive layer 3u is electrically connected to the light shielding layer 3a. The lower conductive layer 3u may be a portion of the light shielding layer 3a or may be connected to (integrally formed with) the light shielding layer 3a. The gate connecting layer 18u is electrically connected to a corresponding gate bus line GL. The gate connecting layer 18u may be a portion of the gate electrode GE or the gate bus line GL, or may be connected to the gate electrode GE or the gate bus line GL.

The source connecting layer 8u is formed in the upper metal layer and is electrically insulated from the source bus line SL. The source connecting layer 8u may be an island portion. The source connecting layer 8u is connected to both a portion of the gate connecting layer 18u and a portion of the lower conductive layer 3u, in the contact holes CHu formed in the insulating layer (upper insulating layer 22 and first interlayer insulating layer 10), the gate insulating layer 9, and the lower insulating layer 5. In this example, the source connecting layer 8u is in direct contact with the gate connecting layer 18u and the lower conductive layer 3u.

The contact hole CHu includes the opening portion 10q formed in the first interlayer insulating layer 10, the opening portion (or cutout portion) 22q formed in the upper insulating layer 22, the opening portion 9q formed in the gate insulating layer 9, and the opening portion 5q formed in the lower insulating layer 5. When viewed from the normal direction of the substrate 1, the opening portion 10q is disposed so as to overlap a portion of the gate connecting layer 18u and a portion of the lower conductive layer 3u (portion of the lower conductive layer 3u that does not overlap the gate connecting layer 18u).

The lower electrode connecting portion 202 can also be manufactured in a manufacturing step of the active matrix substrate 101 described above. The gate insulating layer 9, the gate connecting layer 18u, and the upper insulating layer 22 may be patterned by a method similar to the method described above with reference to FIGS. 3A to 3E. For example, the contact hole CHu can be formed by collectively etching the first interlayer insulating layer 10, the upper insulating layer 22, the gate insulating layer 9, and the lower insulating layer 5 using the resist layer formed on the first interlayer insulating layer 10 and the gate connecting layer 18u as a mask, in a step of etching the first interlayer insulating layer 10.

Since the upper insulating layer 22 is, for example, a photosensitive SOG film (oxide film), the upper insulating layer 22 can be simultaneously etched in the step of etching the first interlayer insulating layer 10. In this case, the side surfaces of the upper insulating layer 22 and the first interlayer insulating layer 10 are at least partially coincided with each other in the contact hole CHu. The side surface of the lower insulating layer 5 is partially coincided with the side surfaces of the gate electrode GE and the gate insulating layer 9 in the contact hole CHu.

<Terminal Portion>

The active matrix substrate 101 may further include a terminal portion disposed in the non-display region.

FIG. 8 is a cross-sectional view illustrating an example of a terminal portion (gate terminal portion) 301 disposed in the non-display region of the active matrix substrate 101.

In the terminal portion 301, the first connecting layer 18t formed in the gate metal layer is electrically connected to the second connecting layer 19t formed using the same transparent conductive film as that of the pixel electrode PE.

The terminal portion 301 is provided with the lower insulating layer 5 formed on the substrate 1, the gate insulating layer 9 disposed on the lower insulating layer 5, a first connecting layer 18t disposed on a portion of the gate insulating layer 9, an insulating layer covering the first connecting layer 18t, a terminal portion contact hole CHt formed in the insulating layer, and a second connecting layer 19t connected to the first connecting layer 18t in the terminal portion contact hole CHt. The first connecting layer 18t may be a portion of the gate bus line GL (for example, end portion of the gate bus line GL). Alternatively, the first connecting layer 18t may be a portion of a connecting wiring electrically connected to the source bus line SL by the source-gate connecting portion.

The first connecting layer 18t is covered with the upper insulating layer 22, the first interlayer insulating layer 10, the inorganic insulating layer 11, and the dielectric layer 17. In this example, the organic insulating layer 12 is not formed in the non-display region, and the organic insulating layer 12 may also be extended on the first connecting layer 18t. Here, the upper insulating layer 22 has a pattern one size larger than the first connecting layer 18t. The upper insulating layer 22 covers the upper surface and the side surface of the first connecting layer 18t, and is in contact with the upper surface of the gate insulating layer 9 (portion of the upper surface of the gate insulating layer 9 located around the first connecting layer 18t). When viewed from the normal direction of the substrate 1, the peripheral edge of the upper insulating layer 22 and the peripheral edge of the gate insulating layer 9 (peripheral edge of the upper surface of the gate insulating layer 9 when the gate insulating layer 9 has a tapered shape) may be coincided with each other.

The terminal portion contact hole CHt that exposes a portion of the first connecting layer 18t is formed in the upper insulating layer 22, the first interlayer insulating layer 10, the inorganic insulating layer 11, and the dielectric layer 17. The second connecting layer 19t is disposed on the dielectric layer 17 and in the terminal portion contact hole CHt, and is connected to the first connecting layer 18t in the terminal portion contact hole CHt. Here, the second connecting layer 19t is in direct contact with the first connecting layer 18t.

The terminal portion 301 can be manufactured in the manufacturing step of the active matrix substrate 101 described above. The gate insulating layer 9, the first connecting layer 18t, and the upper insulating layer 22 may be patterned by a method similar to the method described above with reference to FIGS. 3A to 3E. The terminal portion contact hole CHt can be formed, for example, by collectively etching the upper insulating layer 22, the first interlayer insulating layer 10, and the inorganic insulating layer 11 in a step of etching the dielectric layer 17. Since the upper insulating layer 22 is, for example, a photosensitive SOG film (oxide film), the upper insulating layer 22 is simultaneously etched in a step of etching the insulating layer such as the dielectric layer 17. In this case, the side surfaces of the upper insulating layer 22, the first interlayer insulating layer 10, the inorganic insulating layer 11, and the dielectric layer 17 are coincided with each other in the terminal portion contact hole CHt.

<Another Method for Manufacturing Active Matrix Substrate 101>

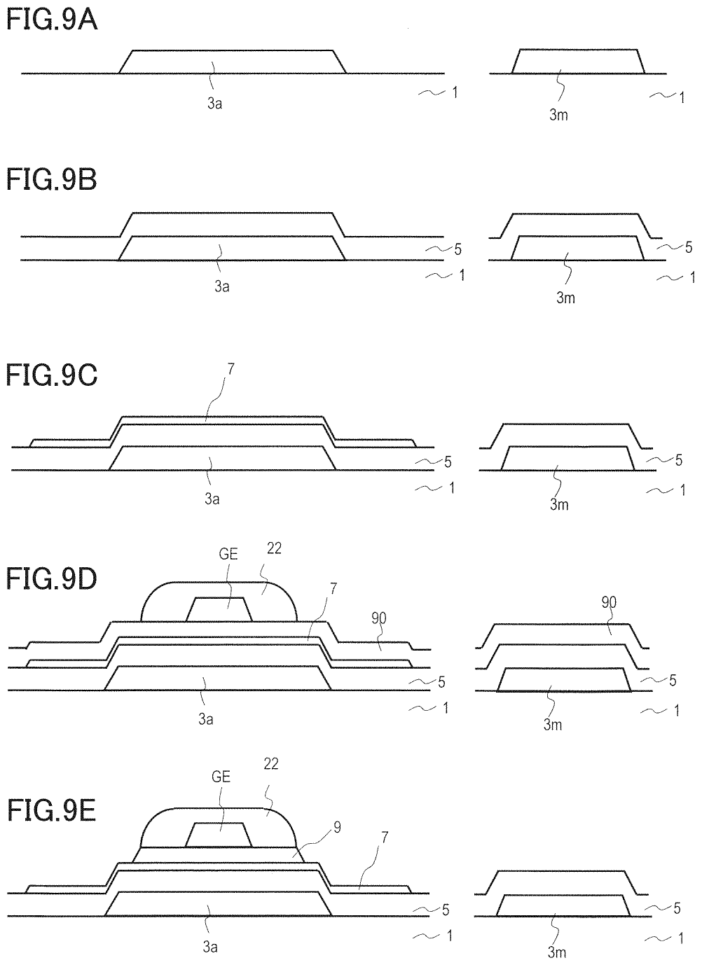

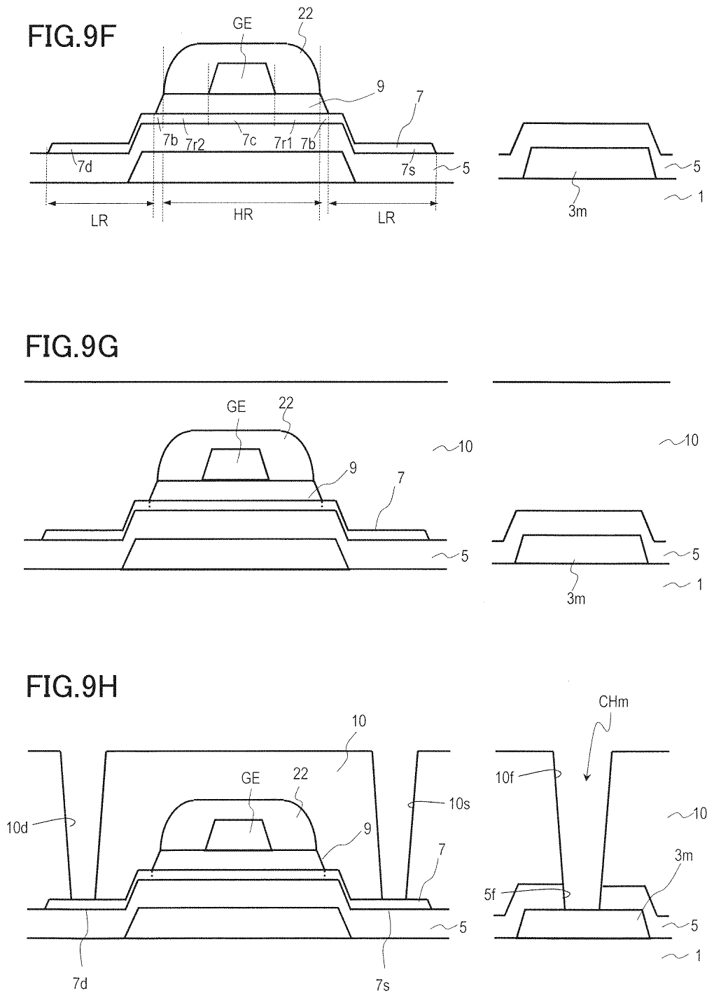

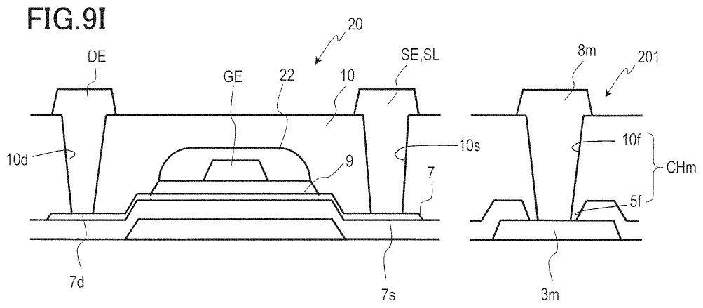

FIGS. 9A to 9I are step sectional views illustrating another method for manufacturing the active matrix substrate 101 of the present embodiment, respectively, and illustrate the forming regions of the TFT 20 and the lower electrode connecting portion 201. The steps after a step of forming the upper metal layer (STEP 8) illustrated in FIG. 9I are the same as the steps illustrated in FIGS. 6J to 6M, and are not illustrated.

The steps illustrated in FIGS. 9A to 9I are similar to the steps described above with reference to FIGS. 6A to 6I, respectively. However, as illustrated in FIG. 9B, a step of forming the lower insulating layer 5 of STEP 2 is different from the above-described step in that the lower insulating layer 5 is not half-etched.

In this example, in STEP 3, as illustrated in FIG. 9C, a step of patterning the oxide semiconductor film is performed with the surfaces of the lower metal layer (surfaces of the light shielding layer 3a and the lower conductive layer 3m) protected by the lower insulating layer 5. Therefore, similarly to the step illustrated in FIG. 6C, damage to the surface of the lower metal layer can be suppressed even when a PAN-based etching solution is used as the etching solution.

In STEP 5, as illustrated in FIG. 9H, when patterning the first interlayer insulating layer 10, the contact hole CHm of the lower electrode connecting portion 201 is formed by collectively etching the first interlayer insulating layer 10 and the lower insulating layer 5 so as to at least partially overlap the lower conductive layer 3m. However, this step is different from the step illustrated in FIG. 6H in that it is necessary to etch the first interlayer insulating layer 10 and the lower insulating layer 5 over the entire thickness when forming the contact hole CHm.

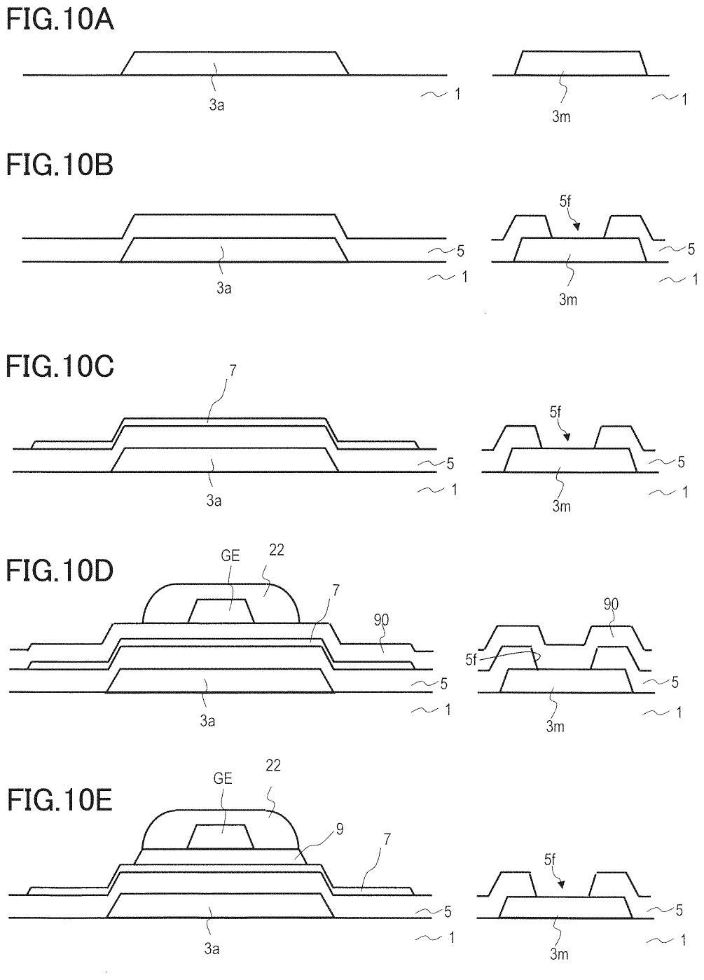

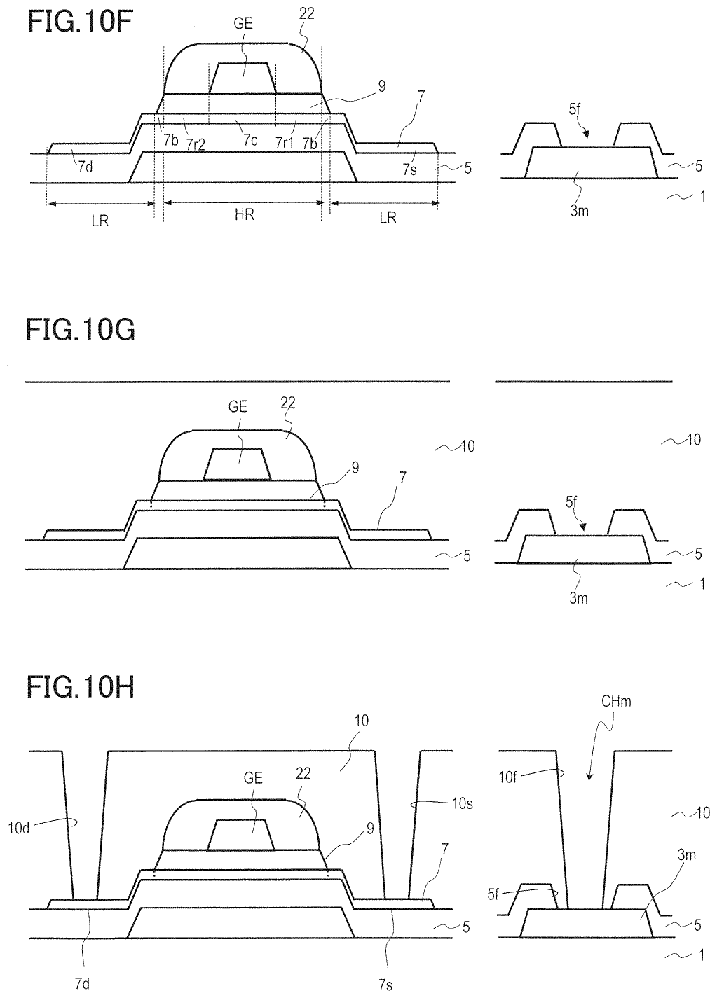

FIGS. 10A to 10I are step sectional views illustrating still another method for manufacturing the active matrix substrate of the present embodiment, respectively, and illustrate the forming regions of the TFT 20 and the lower electrode connecting portion 201. The steps after the step of forming the upper metal layer (STEP 8) illustrated in FIG. 10I are the same as the steps illustrated in FIGS. 6J to 6M, and are not illustrated.

The steps illustrated in FIGS. 10A to 10I are the same as the steps described above with reference to FIGS. 6A to 6M, respectively. However, the steps differ in the following points.

In this method, as illustrated in FIG. 10B, in the step of forming the lower insulating layer 5 of STEP 2, the lower opening portion 5f exposing a portion of the lower conductive layer 3m is formed in the lower insulating layer 5. Thereafter, in STEP 3, the oxide semiconductor film is etched with the surface of the lower conductive layer 3m exposed (FIG. 10C). Therefore, it is preferable to use, for example, an oxalic acid-based etching solution as the etching solution. When a PAN-based etching solution is used, the exposed surface of the lower conductive layer 3m may elute. In this method, as illustrated in FIG. 10H, in a step of patterning the first interlayer insulating layer 10 in STEP 5, when viewed from the normal direction of the substrate 1, the upper opening portion 10f is formed so as to at least partially overlap the lower opening portion 5f. As a result, the contact hole CHm is formed which includes the lower opening portion 5f and the upper opening portion 10f and exposes a portion of the lower conductive layer 3m.

### Second Embodiment

The active matrix substrate according to the second embodiment differs from that of the first embodiment in that the source bus line SL has a structure (lower source structure) disposed on the substrate side of the gate bus line GL.

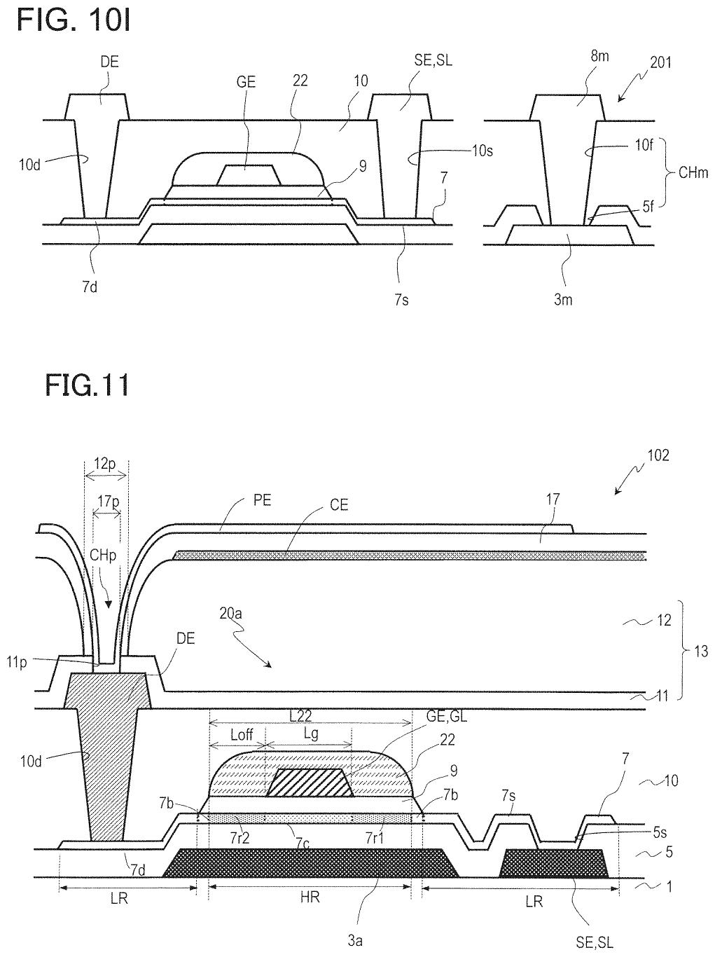

FIG. 11 is a cross-sectional view illustrating a pixel region of an active matrix substrate 102.

The active matrix substrate 102 has a top gate type TFT 20a. In the active matrix substrate 102, the source bus line SL and the source electrode SE of the TFT 20a are formed between the oxide semiconductor layer 7 and the substrate 1. In this example, the source bus line SL and the source electrode SE are formed (in the lower metal layer) using the same conductive film as that of the light shielding layer 3a. The source electrode SE, the source bus line SL, and the light shielding layer 3a are covered with the lower insulating layer 5. The oxide semiconductor layer 7 of the TFT 20a is disposed on the lower insulating layer 5. The first region 7s of the oxide semiconductor layer 7 is connected to the source electrode SE (or source bus line SL) in the source opening portion 5s formed in the lower insulating layer 5. Other structures are similar to those of the active matrix substrate 101.

Although not illustrated, when the light shielding layer 3a of the TFT 20a is used as a lower electrode, the light shielding layer 3a may be connected to the source bus line SL. Alternatively, the light shielding layer 3a may be electrically connected to the wiring in the gate metal layer or the wiring in the upper metal layer. For example, each pixel region may be provided with the lower electrode connecting portion 202 (FIG. 7) that connects the light shielding layer 3a and the gate bus line GL.

<Method for Manufacturing Active Matrix Substrate 102>

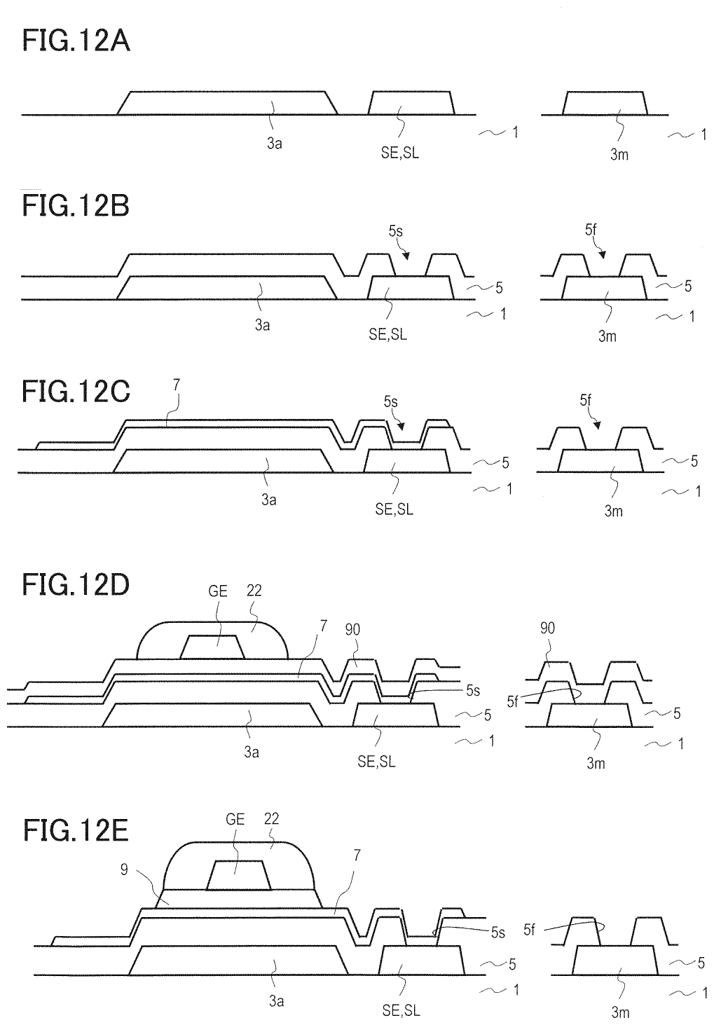

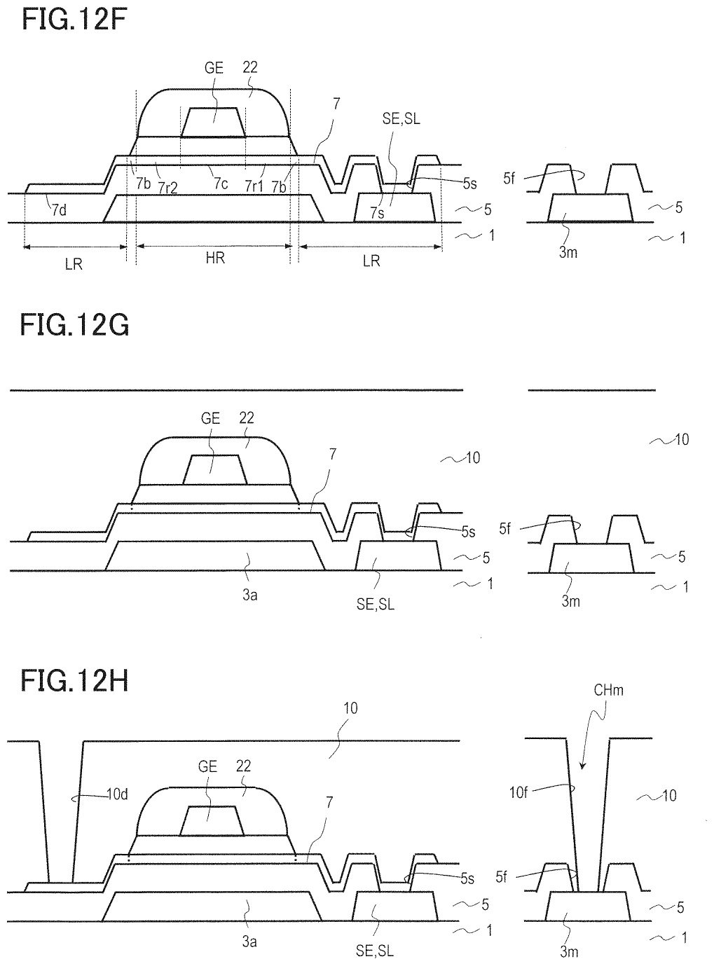

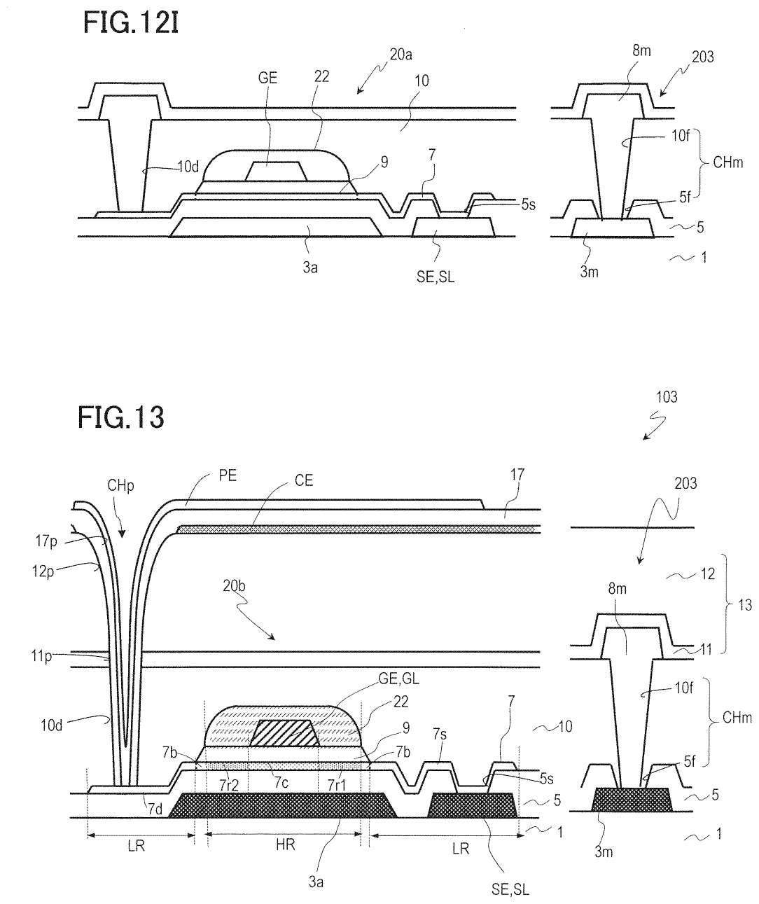

FIGS. 12A to 121 are step sectional views illustrating a method for manufacturing the active matrix substrate 102 having the lower source structure, respectively, and illustrate the forming regions of the TFT 20a and the lower electrode connecting portion 203.

The lower electrode connecting portion 203 may be provided in, for example, the non-display region (peripheral region). As an example, the source bus line SL in the lower metal layer may be extended to the peripheral region, and the source bus line SL may be connected to the wiring in the upper metal layer at the lower electrode connecting portion 203 disposed in the peripheral region. Alternatively, the light shielding layer 3a may be extended to the peripheral region along the gate bus line GL, and the light shielding layer 3a may be fixed at a low potential in the lower electrode connecting portion 203 disposed in the peripheral region.

The steps after the step of forming the upper metal layer (STEP 8) illustrated in FIG. 12I are the same as the steps illustrated in FIGS. 6J to 6M, and are not illustrated.

In the following description, the points different from the steps described in the method for manufacturing in the first embodiment will be described.

In the present embodiment, in STEP 1, a lower conductive film is formed on the substrate 1 and the lower conductive film is patterned. As a result, as illustrated in FIG. 12A, a lower metal layer including the light shielding layer 3a, the source bus line SL, the source electrode SE, and the lower conductive layer 3m is formed.

Next, in STEP 2, as illustrated in FIG. 12B, a lower insulating layer 5 is formed so as to cover the lower metal layer. Subsequently, a source opening portion 5s exposing a portion of the source electrode SE and a lower opening portion 5f exposing a portion of the lower conductive layer 3m are formed in the lower insulating layer 5.

Thereafter, in STEP 3, as illustrated in FIG. 12C, an oxide semiconductor film is formed on the lower insulating layer 5, in the source opening portion 5s, and in the lower opening portion 5f, and patterned to form an oxide semiconductor layer 7. For patterning, for example, an oxalic acid-based etching solution is used. When a PAN-based etching solution is used, the portion of the lower conductive layer 3m exposed by the lower opening portion 5f may be eluted.

Next, in STEP 4, as illustrated in FIGS. 12D to 12F, the gate insulating layer 9, the gate electrode GE, and the upper insulating layer 22 are formed by the same method as that of the first embodiment, and the resistance lowering treatment is performed.

Subsequently, in STEP 5, as illustrated in FIGS. 12G and 12H, a first interlayer insulating layer 10 is formed, and the first interlayer insulating layer 10 is patterned. A drain opening portion 10d exposing a portion of the second region 7d of the oxide semiconductor layer 7 is formed in the first interlayer insulating layer 10 by patterning. In the forming region of the lower electrode connecting portion, an upper opening portion 10f is formed so as to at least partially overlap the lower opening portion 5f when viewed from the normal direction of the substrate 1. As described above, a contact hole CHm is obtained which includes the lower opening portion 5f and the upper opening portion 10f and exposes a portion of the lower conductive layer 3m.

Thereafter, in STEP 7, a conductive film (upper conductive film) is formed on the first interlayer insulating layer 10, in the drain opening portion 10d, and in the contact hole CHm, and the upper conductive film is patterned. As a result, as illustrated in FIG. 12I, a drain electrode DE is formed which is disposed on the first interlayer insulating layer 10 and in the drain opening portion 10d, and is connected to the second region 7d in the drain opening portion 10d. In the forming region of the lower electrode connecting portion, an upper conductive layer 8m is formed which is disposed on the first interlayer insulating layer 10 and in the contact hole CHm, and is connected to the lower conductive layer 3m in the contact hole CHm. As described above, a TFT 20a and a lower electrode connecting portion 203 are obtained.

The method for manufacturing the active matrix substrate 102 is not limited to the example illustrated in FIGS. 12A to 121. In STEP 2, the lower opening portion 5f may not be formed in the lower insulating layer 5 in the forming region of the lower electrode (refer to FIG. 9B), and in STEP 6, the contact hole CHm may be formed by collectively etching the first interlayer insulating layer 10 and the lower insulating layer 5. Alternatively, in STEP 2, the lower insulating layer 5 may be partially thinned by half etching to form a thin film portion 5h (refer to FIG. 6B). In this case, in STEP 6, the contact holes CHm may be formed by collectively etching the thinned portions of the first interlayer insulating layer 10 and the lower insulating layer 5. According to these methods, a step of patterning the oxide semiconductor film in STEP 3 can be performed with the entire surface of the lower conductive layer 3m covered with the lower insulating layer 5. Therefore, the etching solution used in the step of patterning the oxide semiconductor film is not limited to the oxalic acid-based etching solution, and the PAN-based etching solution can be used.

The configuration of the lower electrode connecting portion in the present embodiment is not limited to the configuration illustrated in FIG. 11. For example, the lower electrode may be electrically connected to the source bus line SL by connecting (integrally forming) the light shielding layer (lower electrode) of the TFT 20a and the source bus line SL (or the source electrode SE).

Alternatively, a lower electrode connecting portion having the same structure as that in FIG. 7 may be formed and the lower electrode may be electrically connected to the gate electrode GE.

### Modification Example 1

FIG. 13 is a cross-sectional view illustrating a pixel region of an active matrix substrate 103 according to Modification Example 1 having a lower source structure. The active matrix substrate 103 is provided with a TFT 20b associated with each pixel region and a lower electrode connecting portion 203.

Modification Example 1 is different from the active matrix substrate 102 in that the TFT 20b does not have the drain electrode DE, and the pixel electrode PE is in direct contact with the second region 7d of the oxide semiconductor layer 7 in the pixel contact hole CHp. According to Modification Example 1, since the drain electrode DE is not formed in the pixel region PIX, it is possible to further increase a pixel aperture ratio.

The active matrix substrate 103 can be manufactured by the same method as that of the active matrix substrate 102. However, the portion of the upper conductive film located in the drain opening portion 10d is removed by etching. The pixel electrode PE is formed so as to be in direct contact with the second region 7d of the oxide semiconductor layer 7 in the pixel contact hole CHp formed of the opening portion 17p, the opening portion 12p, the opening portion 11p, and the drain opening portion 10d.

### Modification Example 2

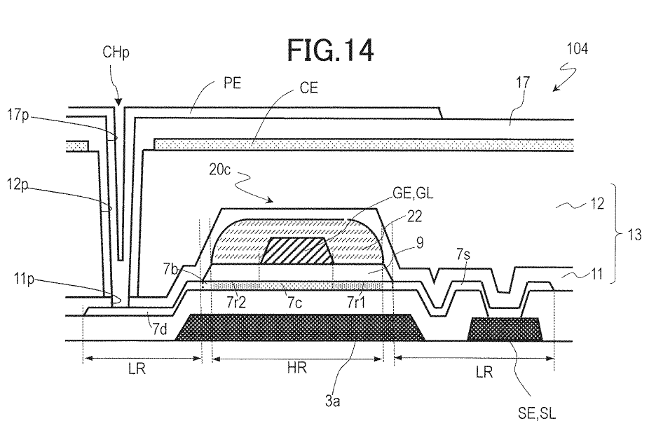

FIG. 14 is a cross-sectional view illustrating a pixel region of an active matrix substrate 104 according to Modification Example 2 having a lower source structure. The active matrix substrate 104 is provided with a TFT 20c associated with each pixel region.

The active matrix substrate 104 may not have another metal layer (upper metal layer) between the gate metal layer and the common electrode CE or the pixel electrode PE. As a result, since the first interlayer insulating layer 10 is unnecessary, the depth of the pixel contact hole CHp can be reduced. Therefore, the pixel contact hole CHp reaching the oxide semiconductor layer 7 can be formed more easily.

The structure and the method for manufacturing the active matrix substrate of the embodiment according to the present invention are not limited to the structure and the method exemplified above. The active matrix substrate of the embodiment according to the present invention can be applied to a display devices such as a liquid crystal display device, an organic EL display device, and a micro LED display device, an imaging device such as a radiation detector and an image sensor, an electronic device such as an image input device and a fingerprint reading device, and the like.

<About Oxide Semiconductor>

The oxide semiconductor included in the oxide semiconductor layer 7 may be an amorphous oxide semiconductor or a crystalline oxide semiconductor having a crystalline portion. Examples of the crystalline oxide semiconductor include a polycrystalline oxide semiconductor, a microcrystalline oxide semiconductor, and a crystalline oxide semiconductor in which a c-axis is substantially perpendicular to a layer surface.

The oxide semiconductor layer 7 may have a stacked structure of two or more layers. In the case where the oxide semiconductor layer 7 has a stacked structure, the oxide semiconductor layer 7 may include an amorphous oxide semiconductor layer and a crystalline oxide semiconductor layer. Alternatively, a plurality of crystalline oxide semiconductor layers having different crystal structures may be included. A plurality of amorphous oxide semiconductor layers may be included. In a case where the oxide semiconductor layer 7 has a two-layer structure including an upper layer and a lower layer, the energy gap of the oxide semiconductor included in a layer located on the gate electrode side (lower layer for bottom gate type, and upper layer for top gate type) of the two layers may be smaller than the energy gap of the oxide semiconductor included in a layer located on a side opposite to the gate electrode (upper layer for bottom gate type, and lower layer for top gate type). However, in a case where the difference in energy gap between these layers is relatively small, the energy gap of the oxide semiconductor in the layer located on the gate electrode side may be larger than the energy gap of the oxide semiconductor in the layer located on the side opposite to the gate electrode.

Materials, structures, film formation methods, structures of oxide semiconductor layers having a stacked structure, and the like of the amorphous oxide semiconductor and each of the above crystalline oxide semiconductors are described in, for example, Japanese Unexamined Patent Application Publication No. 2014-007399. For reference, the entire contents disclosed in Japanese Unexamined Patent Application Publication No. 2014-007399 are incorporated herein.

The oxide semiconductor layer 7 may include, for example, at least one metal element among In, Ga, and Zn. In the present embodiment, the oxide semiconductor layer 7 includes, for example, an In—Ga—Zn—O-based semiconductor (for example, indium gallium zinc oxide). Here, the In—Ga—Zn—O-based semiconductor is a ternary oxide of indium (In), gallium (Ga), and zinc (Zn), a ratio (composition ratio) of In, Ga, and Zn is not particularly limited, and includes, for example, In:Ga:Zn=2:2:1, In:Ga:Zn=1:1:1, In:Ga:Zn=1:1:2, and the like. Such an oxide semiconductor layer 7 can be formed of an oxide semiconductor film including an In—Ga—Zn—O-based semiconductor.

The In—Ga—Zn—O-based semiconductor may be amorphous or crystalline. As the crystalline In—Ga—Zn—O-based semiconductor, a crystalline In—Ga—Zn—O-based semiconductor in which the c-axis is oriented substantially perpendicular to the layer surface is preferable.

The crystal structure of a crystalline In—Ga—Zn—O-based semiconductor is disclosed in, for example, above Japanese Unexamined Patent Application Publication No. 2014-007399, Japanese Unexamined Patent Application Publication No. 2012-134475, and Japanese Unexamined Patent Application Publication No. 2014-209727. For reference, the entire contents disclosed in Japanese Unexamined Patent Application Publication No. 2012-134475 and Japanese Unexamined Patent Application Publication No. 2014-209727 are incorporated herein. A TFT having an In—Ga—Zn—O-based oxide semiconductor layer has high mobility (more than 20 times that of an a-Si TFT) and low leak current (less than 1/100 that of an a-Si TFT). Therefore, the TFT is suitably used as a driving TFT (for example, TFT included in a driving circuit provided on the same substrate as that of a display region around a display region including a plurality of pixels) and a pixel TFT (TFT provided in a pixel).

The oxide semiconductor layer 7 may include another oxide semiconductor instead of the In—Ga—Zn—O-based semiconductor. For example, an In—Sn—Zn—O-based semiconductor (for example, In₂O₃—SnO₂—ZnO; InSnZnO) may be included. The In—Sn—Zn—O-based semiconductor is a ternary oxide of indium (In), tin (Sn), and zinc (Zn). Alternatively, the oxide semiconductor layer 7 may include an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, a cadmium oxide (CdO), Mg—Zn—O-based semiconductor, an In—Ga—Sn—O-based semiconductor, an In—Ga—O-based semiconductor, a Zr—In—Zn—O-based semiconductor, a Hf—In—Zn—O-based semiconductor, an Al—Ga—Zn—O-based semiconductor, a Ga—Zn—O-based semiconductor, an In—Ga—Zn—Sn—O-based semiconductor, and the like.

While there have been described what are at present considered to be certain embodiments of the invention, it will be understood that various modifications may be made thereto, and it is intended that the appended claim cover all such modifications as fall within the true spirit and scope of the invention.

What is claimed is:

1. An active matrix substrate that includes a display region having a plurality of pixel regions, the active matrix substrate comprising:
a substrate;
a plurality of gate bus lines and a plurality of source bus lines that are supported on a main surface of the substrate;
an oxide semiconductor TFT that is disposed in association with each of the plurality of pixel regions, and that includes an oxide semiconductor layer, a gate insulating layer disposed on a portion of the oxide semiconductor layer, and a gate electrode disposed on a portion of the gate insulating layer and electrically connected to one of the plurality of gate bus lines;
a pixel electrode that is disposed in each of the plurality of pixel regions; and
an upper insulating layer that is formed of a photosensitive SOG film or a photosensitive resin film, and that is disposed on the gate electrode and the gate insulating layer so as to cover an upper surface and a side surface of the gate electrode, wherein
the oxide semiconductor layer includes a high resistance region, and a first region and a second region that are respectively located on both sides of the high resistance region and have a lower resistivity than that of the high resistance region, the first region is electrically connected to one of the plurality of source bus lines, and the second region is electrically connected to the pixel electrode,
the high resistance region includes a channel region that overlaps the gate electrode when viewed from a normal direction of the main surface of the substrate, a first channel offset region located between the first region and the channel region, and a second channel offset region located between the second region and the channel region, and
the upper insulating layer is disposed so as to overlap the channel region, the first channel offset region, and the second channel offset region, and so as not to overlap any of the first region and the second region, when viewed from the normal direction of the main surface of the substrate.

2. The active matrix substrate according to claim 1, wherein
the upper insulating layer is in direct contact with the upper surface and the side surface of the gate electrode and a portion of an upper surface of the gate insulating layer which is located around the gate electrode, and is not in direct contact with the oxide semiconductor layer, and
a peripheral edge of the upper insulating layer and a peripheral edge of the upper surface of the gate insulating layer are coincided with each other when viewed from the normal direction of the main surface of the substrate.

3. The active matrix substrate according to claim 1, wherein
the gate electrode is formed using the same conductive film as that of the plurality of gate bus lines,
each of the plurality of gate bus lines is located on a portion of the gate insulating layer, and
an upper surface and a side surface of each of the plurality of gate bus lines are covered with the upper insulating layer.

4. The active matrix substrate according to claim 1, further comprising:
a first interlayer insulating layer that covers the oxide semiconductor TFT and the upper insulating layer, wherein
the oxide semiconductor TFT further includes a source electrode formed of the same conductive film as that of the plurality of source bus lines, and the source electrode is disposed on the first interlayer insulating layer and in a source opening portion formed in the first interlayer insulating layer, and is connected to the first region of the oxide semiconductor layer in the source opening portion.

5. The active matrix substrate according to claim 4, wherein
the oxide semiconductor TFT further includes a lower electrode or a light shielding layer that is disposed on the substrate side of the channel region of the oxide semiconductor layer via a lower insulating layer.

6. The active matrix substrate according to claim 5, further comprising:
a lower electrode connecting portion that electrically connects the lower electrode to the one of the plurality of source bus lines, wherein
the lower electrode connecting portion includes
a lower conductive layer that is electrically connected to the lower electrode,
the lower insulating layer and the first interlayer insulating layer that are extended on the lower conductive layer, and
an upper conductive layer that is electrically connected to the one of the plurality of source bus lines, and
the upper conductive layer is disposed on the first interlayer insulating layer and in a contact hole formed in the first interlayer insulating layer and the lower insulating layer, and is connected to the lower conductive layer in the contact hole.

7. The active matrix substrate according to claim 6, wherein
the contact hole includes an opening portion of the lower insulating layer and an opening portion of the first interlayer insulating layer, and a side surface of the opening portion of the lower insulating layer and a side surface of the opening portion of the first interlayer insulating layer are coincided with each other.

8. The active matrix substrate according to claim 6, wherein
the lower insulating layer includes a thin film portion disposed so as to overlap at least a portion of the lower conductive layer when viewed from the normal direction of the main surface of the substrate, and having a smaller thickness than that of the other portion of the lower conductive layer, and
at least a portion of the opening portion of the lower insulating layer is formed in the thin film portion.

9. The active matrix substrate according to claim 5, further comprising:
a lower electrode connecting portion that electrically connects the lower electrode to the one of the plurality of gate bus lines, wherein
the lower electrode connecting portion includes
a lower conductive layer that is electrically connected to the lower electrode,
the lower insulating layer that is extended on the lower conductive layer,
a gate insulating layer that is disposed on a portion of the lower conductive layer via the lower insulating layer,
a gate connecting layer that is electrically connected to the one of the plurality of gate bus lines, and that is disposed on a portion of the gate insulating layer,
the upper insulating layer and the first interlayer insulating layer that are extended on the gate connecting layer, and
a source connecting layer that is formed using the same conductive film as that of the plurality of source bus lines, and that is electrically insulated from the plurality of source bus lines,
the source connecting layer is disposed on the first interlayer insulating layer and in a contact hole formed in the first interlayer insulating layer, the upper insulating layer, the gate insulating layer, and the lower insulating layer, and is connected to the lower conductive layer and the gate connecting layer in the contact hole, and
a side surface of an opening portion of the upper insulating layer is coincided with a side surface of an opening portion of the first interlayer insulating layer in the contact hole.

10. The active matrix substrate according to claim 1, wherein
the oxide semiconductor TFT further includes a source electrode formed of the same conductive film as that of the plurality of source bus lines,
the active matrix substrate further comprises a lower insulating layer that covers the source electrode and the plurality of source bus lines,
the oxide semiconductor layer is disposed on the lower insulating layer, and
the first region of the oxide semiconductor layer is disposed on the lower insulating layer and in a source opening portion formed in the lower insulating layer, and is connected to the source electrode in the source opening portion.

11. The active matrix substrate according to claim 10, further comprising:
an insulating layer that covers the oxide semiconductor layer, the gate electrode, and the upper insulating layer, wherein
the pixel electrode is disposed on the insulating layer and is in direct contact with the second region of the oxide semiconductor layer in a pixel contact hole formed in the insulating layer.

12. The active matrix substrate according to claim 10, further comprising:
a first interlayer insulating layer that covers the oxide semiconductor TFT and the upper insulating layer, wherein
the oxide semiconductor TFT further includes a drain electrode, and the drain electrode is disposed on the first interlayer insulating layer and in a drain opening portion formed in the first interlayer insulating layer, and is connected to the second region of the oxide semiconductor layer in the drain opening portion, and
the pixel electrode is electrically connected to the second region via the drain electrode.

13. The active matrix substrate according to claim 10, wherein
the oxide semiconductor TFT further includes a lower electrode or a light shielding layer that is disposed on the substrate side of the channel region of the oxide semiconductor layer via the lower insulating layer, and
the lower electrode or the light shielding layer is formed using the same conductive film as that of the plurality of source bus lines.

14. The active matrix substrate according to claim 1, wherein
the upper insulating layer is formed of the photosensitive SOG film.

15. The active matrix substrate according to claim 1, wherein
the oxide semiconductor layer includes an In—Ga—Zn—O-based semiconductor.

16. The active matrix substrate according to claim 15, wherein
the In—Ga—Zn—O-based semiconductor includes a crystalline portion.

17. A method for manufacturing an active matrix substrate that includes a display region having a plurality of pixel regions, and an oxide semiconductor TFT and a pixel electrode associated with each pixel region, the method comprising:
a step (A) of forming the oxide semiconductor layer of each of the oxide semiconductor TFTs, by forming an oxide semiconductor film on a main surface of a substrate and patterning the oxide semiconductor film;
a step (B) of forming a gate insulating film that covers the oxide semiconductor layer;
a step (C) of forming a resist layer from a resist film, by forming a gate conductive film and the resist film in this order on the gate insulating film, and exposing and developing the resist film using a photomask;
a step (D) of forming a gate electrode of each of the oxide semiconductor TFTs by performing etching of the gate conductive film using the resist layer as a mask, and subsequently, removing the resist layer, in which the etching is performed under a condition such that a width of the gate electrode is smaller than a width of the resist layer, and a region of the oxide semiconductor layer which overlaps the gate electrode is a channel region, when viewed from a normal direction of the main surface of the substrate;
a step (E) of forming a photosensitive SOG film or a photosensitive resin film so as to cover the gate electrode and the gate insulating film;
a step (F) of forming an upper insulating layer that covers an upper surface and a side surface of the gate electrode, by exposing, developing, and baking the photosensitive SOG film or the photosensitive resin film by using again the photomask used when forming the resist layer;
a step (G) of patterning the gate insulating film using the upper insulating layer as a mask, and forming a gate insulating layer that covers a portion of the oxide semiconductor layer, in which when viewed from the normal direction of the main surface of the substrate, the gate insulating layer overlaps the channel region of the oxide semiconductor layer and regions located on both sides of the channel region, the regions located on both sides of the channel region are respectively first and second channel offset regions, and a first region of the oxide semiconductor layer located on a side of the first channel offset region opposite to the channel region and a second region of the oxide semiconductor layer located on a side of the second channel offset region opposite to the channel region are exposed from the upper insulating layer and the gate insulating layer; and
a step (H) of performing a resistance lowering treatment of the oxide semiconductor layer to cause a resistivity of the first region and the second region to be smaller than a resistivity of the channel region, the first channel offset region, and the second channel offset region, in which the first region is a region electrically connected to a source electrode of the oxide semiconductor TFT, and the second region is a region electrically connected to the pixel electrode.

18. The method for manufacturing according to claim 17, wherein
the exposing is performed under a condition that a width of the upper insulating layer is larger than a width of the photomask, in the step (F).

19. The method for manufacturing according to claim 17, further comprising:
before the step (A),
a step (a) of forming a lower electrode of each of the oxide semiconductor TFTs and a lower conductive layer electrically connected to the lower electrode, by forming a lower conductive film on the substrate and patterning the lower conductive film; and
a step (b) of forming a lower insulating layer that covers the lower conductive layer and the lower electrode, wherein
in the step (A), the oxide semiconductor layer is formed on the lower insulating layer, and
the method further comprises
after the step (H),
a step (c) of forming an interlayer insulating layer that covers each of the oxide semiconductor TFTs and the upper insulating layer;
a step (d) of forming a contact hole that exposes a portion of the lower insulating layer by collectively etching the interlayer insulating layer and the lower insulating layer; and
a step (e) of forming an upper conductive layer connected to the lower conductive layer in the contact hole, by forming an upper conductive film on the interlayer insulating layer and in the contact hole, and patterning the upper conductive film.

20. The method for manufacturing according to claim 19, wherein
the step (b) includes a step of thinning a portion of a region of the lower insulating layer which overlaps the lower conductive layer to form a thin film portion, and
the contact hole is formed in the thin film portion of the lower insulating layer in the step (d).
